(19) United States
(12) Patent Application Publication
(10) Pub. No.: US 2026/0081106 A1
(43) Pub. Date: Mar. 19, 2026

(54) MULTI-CHARGED PARTICLE BEAM WRITING APPARATUS

(71) Applicant: NuFlare Technology, Inc., Yokohama-shi (JP)

(72) Inventors: Toshiki KIMURA, Yokohama-shi (JP); Hirofumi MORITA, Setagaya-ku (JP)

(73) Assignee: NuFlare Technology, Inc., Yokohama-shi (JP)

(21) Appl. No.: 19/309,707

(22) Filed: Aug. 26, 2025

(30) Foreign Application Priority Data
Sep. 13, 2024 (JP) 2024-159595

(51) Int. Cl. H01J 37/317; H01J 37/04; H01J 37/147; H01J 37/304

(52) U.S. Cl. CPC H01J 37/3177; H01J 37/045; H01J 37/1471; H01J 37/3045; H01J 2237/0435

(57) ABSTRACT

According to one aspect of the present invention, a multi-charged particle beam writing apparatus, includes: a blanking aperture array mechanism having a blanking aperture array chip having a plurality of blankers for individually switching incident multi-charged particle beams between a beam ON state and a beam OFF state by beam deflection and a mounting board configured to support the blanking aperture array chip, a power supply plane for supplying power to the blanking aperture array chip being formed in the mounting board; a limiting aperture substrate configured to block a beam in the beam OFF state among the multi-charged particle beams having passed through the blanking aperture array mechanism; a current acquisition circuit configured to acquire a current flowing through the power supply plane; and one or more stages of deflectors configured to deflect the multi-charged particle beams having passed through the blanking aperture array mechanism.

### CROSS-REFERENCE TO RELATED APPLICATION

This application is based upon and claims the benefit of priority from prior Japanese Patent Application No. 2024-159595 filed on Sep. 13, 2024 in Japan, the entire contents of which are incorporated herein by reference.

### BACKGROUND OF THE INVENTION

### Field of the Invention

One aspect of the present invention relates to a multi-charged particle beam writing (or “drawing”) apparatus, for example, a method for correcting the positional deviations of multiple electron beams due to a magnetic field generated by a mechanism for individually blanking multiple electron beams.

### Related Art

Lithography technology, which is responsible for the progress of miniaturization of semiconductor devices, is an extremely important process that is the only pattern generation process among the semiconductor manufacturing processes. In recent years, as LSIs have become more highly integrated, the circuit line width required for semiconductor devices has become smaller year by year. Here, electron beam lithography technology is basically excellent in terms of resolution, and writing is performed on a wafer and the like using an electron beam.

For example, there is a writing apparatus using multiple beams. Compared to the case of writing using a single electron beam, using multiple beams allows irradiation using a large amount of beams at a time, resulting in a significant improvement in throughput. In such a multi-beam type writing apparatus, for example, an electron beam emitted from an electron emission source passes through a mask having a plurality of holes to form multiple beams, and each of the multiple beams is subjected to blanking control so that each beam that is not blocked is demagnified by an optical system, deflected by a deflector, and emitted to a desired position on a target object.

In multi-beam writing, patterns are formed by individually controlling the beam irradiation time of an electron beam incident on a target object. For this reason, a mounting board, on which a blanking aperture array chip having a plurality of blanker functions for individual beam OFF of a beam whose beam irradiation time is zero or after a desired beam irradiation time has passed is arranged, is mounted in the writing apparatus.

It has been found that a magnetic field generated by a circuit current flowing through such a mounting board causes a positional deviation in an electron beam passing through the blanking aperture array chip. If such a positional deviation occurs, the writing accuracy decreases.

Here, although this is not related to the blanking aperture array mechanism in multi-beam writing, a technique is disclosed for a VSB type single-beam writing apparatus, in which the positional deviation of an electron beam on a target object surface based on a first magnetic field due to an objective lens and a second magnetic field due to an eddy current generated by the first magnetic field and the movement of a stage is corrected by beam deflection of a main deflector (see Published Unexamined Japanese Patent Application No. 2008-277373).

### BRIEF SUMMARY OF THE INVENTION

According to one aspect of the present invention, a multi-charged particle beam writing apparatus, includes:
a blanking aperture array mechanism having
   a blanking aperture array chip having a plurality of blankers for individually switching incident multi-charged particle beams between a beam ON state and a beam OFF state by beam deflection and
   a mounting board configured to support the blanking aperture array chip, a power supply plane for supplying power to the blanking aperture array chip being formed in the mounting board;
a limiting aperture substrate configured to block a beam in the beam OFF state among the multi-charged particle beams having passed through the blanking aperture array mechanism;
a current acquisition circuit configured to acquire a current flowing through the power supply plane;
one or more stages of deflectors configured to deflect the multi-charged particle beams having passed through the blanking aperture array mechanism;
a deflector control circuit configured to control the one or more stages of deflectors so as to correct positional deviations of the multi-charged particle beams due to the current flowing through the power supply plane;
a stage, a target object being placed on the stage; and
an electron optical system configured to irradiate the target object with the multi-charged particle beams with positional deviations corrected.

According to another aspect of the present invention, a multi-charged particle beam writing apparatus, includes:
a blanking aperture array mechanism having
   a blanking aperture array chip having a plurality of blankers for individually switching incident multi-charged particle beams between a beam ON state and a beam OFF state by beam deflection and
   a mounting board configured to support the blanking aperture array chip, a power supply plane for supplying power to the blanking aperture array chip being formed in the mounting board;
a limiting aperture substrate configured to block a beam in the beam OFF state among the multi-charged particle beams having passed through the blanking aperture array mechanism;
one or more stages of deflectors configured to deflect the multi-charged particle beams having passed through the blanking aperture array mechanism;
a storage device configured to store, in order of shots, correction amount information defining an amount of correction for correcting positional deviations of the multi-charged particle beams due to a current flowing through the power supply plane, the amount of correction being calculated in advance offline;
a deflector control circuit configured to control, for each shot, the one or more stages of deflectors using the amount of correction for a shot so as to correct the positional deviations of the multi-charged particle beams due to the current flowing through the power supply plane with reference to the correction amount information;
a stage, a target object being placed on the stage; and
an electron optical system configured to irradiate the target object with the multi-charged particle beams with positional deviations corrected.

### BRIEF DESCRIPTION OF THE DRAWINGS

FIG. 1 is a conceptual diagram showing the configuration of a writing apparatus according to Embodiment 1;

FIG. 2 is a conceptual diagram showing the configuration of a shaping aperture array substrate in Embodiment 1;

FIG. 3 is a cross-sectional view showing the configuration of a central portion of a blanking aperture array mechanism in Embodiment 1;

FIG. 4 is a conceptual top view showing a part of the configuration within a membrane region of a blanking aperture array chip in Embodiment 1;

FIG. 5 is a diagram showing an example of an individual blanking mechanism in Embodiment 1;

FIG. 6 is a diagram showing an example of a connection configuration of a shift register in Embodiment 1;

FIG. 7 is a diagram showing an example of divided shots of multiple electron beams in Embodiment 1;

FIG. 8 is a conceptual diagram showing the internal configuration of an individual blanking control circuit and a common blanking control circuit in Embodiment 1;

FIG. 9 is a top view of an example of the blanking aperture array mechanism in Embodiment 1;

FIG. 10 is a cross-sectional view of an example of the blanking aperture array mechanism in Embodiment 1;

FIG. 11 is a diagram for explaining the positional deviations of multiple electron beams and a correction 30 method in Embodiment 1;

FIG. 12 is a diagram for explaining an example of the positional deviations of multiple electron beams in Embodiment 1;

FIG. 13 is a diagram showing an example of the relationship between the operating current and the amount of positional deviation in Embodiment 1;

FIG. 14 is a conceptual diagram for explaining an example of the writing operation in Embodiment 1;

FIG. 15 is a diagram showing an example of a region irradiated with multiple beams and a writing target pixel in Embodiment 1;

FIG. 16 is a diagram for explaining an example of a multi-beam writing operation in Embodiment 1;

FIG. 17 is a diagram showing an example of the configuration of a writing apparatus according to a modification example of Embodiment 1;

FIG. 18 is a diagram showing an example of the configuration of a writing apparatus according to Embodiment 2;

FIG. 19 is a diagram showing an example of the configuration of a writing apparatus according to Embodiment 3;

FIG. 20 is a diagram showing an example of the configuration of a writing apparatus according to Embodiment 4; and

FIG. 21 is a diagram showing an example of the configuration of a writing apparatus according to Embodiment 5.

### DETAILED DESCRIPTION OF THE INVENTION

In the following embodiments, an apparatus is provided that can correct the positional deviations of multi-charged particle beams due to a magnetic field generated by a circuit current flowing through a mounting board on which a blanking aperture array chip, through which multi-charged particle beams pass, is arranged.

In addition, in the following embodiments, a configuration using an electron beam as an example of a charged particle beam will be described. However, the charged particle beam is not limited to an electron beam, and may be a beam using a charged particle such as an ion beam.

### Embodiment 1

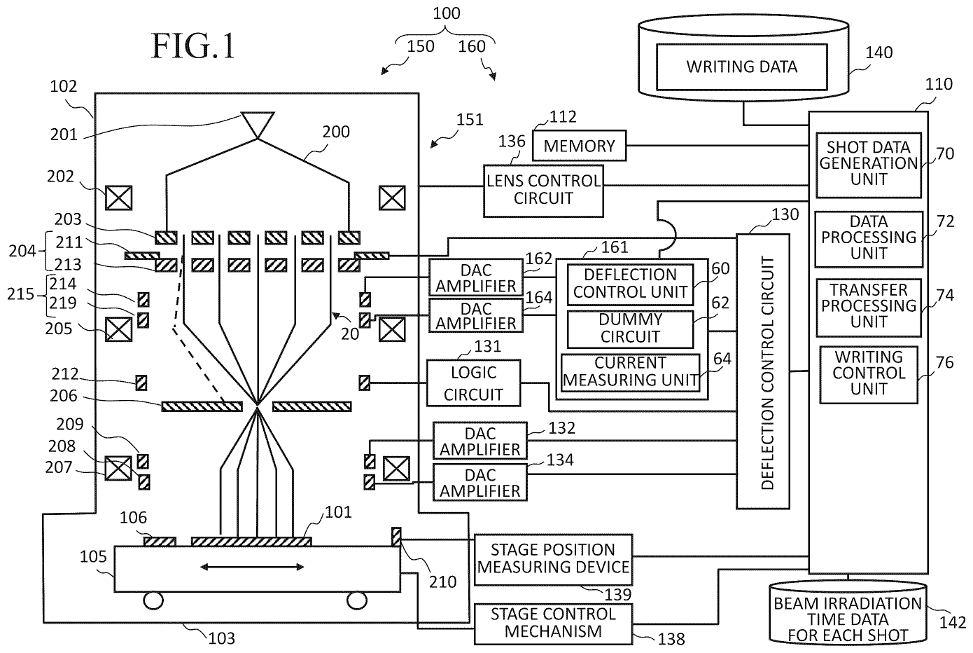

FIG. 1 is a conceptual diagram showing the configuration of a writing apparatus according to Embodiment 1. In FIG. 1, a writing apparatus 100 includes a writing mechanism 150 and a control system circuit 160. The writing apparatus 100 is an example of a multi-charged particle beam writing apparatus and an example of a multi-charged particle beam exposure apparatus. The writing mechanism 150 includes an electron optical column 102 (electron beam column) and a writing chamber 103. In the electron optical column 102, an electron emission source 201, an illumination lens 202, a shaping aperture array substrate 203, a blanking aperture array mechanism 204, one or more stages of deflectors 215, a demagnifying lens 205, a deflector 212, a limiting aperture substrate 206, an objective lens 207, a deflector 208, and a deflector 209 are arranged.

The electron emission source 201, the illumination lens 202, the shaping aperture array substrate 203, the blanking aperture array mechanism 204, the one or more stages of deflectors 215, the demagnifying lens 205, the deflector 212, the limiting aperture substrate 206, the objective lens 207, the deflector 208, and the deflector 209 form an electron optical system 151.

In the example of FIG. 1, a case is shown in which two-stage deflectors 214 and 219 are arranged as one or more stages of deflectors 215. In addition, in the example of FIG. 1, an electrostatic deflector is shown as an example of one or more stages of deflectors 215 (deflectors 214 and 219), but the invention is not limited thereto. For example, a magnetic deflector may be used. Alternatively, when two or more stages of deflectors 214 and 219 are used, an electrostatic deflector and a magnetic deflector may be combined. In other words, at least one of an electrostatic deflector and a magnetic deflector is used as one or more stages of deflectors 215 (deflectors 214 and 219).

In addition, in the example of FIG. 1, a case is shown in which one or more stages of deflectors 215 (deflectors 214 and 219) are arranged between the blanking aperture array mechanism 204 and the demagnifying lens 205, but the invention is not limited thereto. One or more stages of deflector 215 (deflectors 214 and 219) may be arranged between the blanking aperture array mechanism 204 and a target object 101. Preferably, one or more stages of deflectors 215 (deflectors 214 and 219) are arranged between the blanking aperture array mechanism 204 and the limiting aperture substrate 206.

The blanking aperture array mechanism 204 includes a mounting board 211 and a blanking aperture array chip 213. In a central portion of the mounting board 211, an opening through which all of multiple electron beams 20 can pass is formed. The blanking aperture array chip 213 is suspended from the mounting board 211 so as to block the opening. In other words, the blanking aperture array chip 213 is arranged so that the outer periphery thereof is supported by the mounting board 211. The blanking aperture array chip 213 may be arranged on the mounting board 211.

An XY stage 105 is arranged in the writing chamber 103. On the XY stage 105, a target object 101 such as a mask, which becomes a writing target substrate during writing (during exposure), is arranged. The target object 101 includes an exposure mask used in manufacturing a semiconductor device, a semiconductor substrate (silicon wafer) on which a semiconductor device is manufactured, and the like. In addition, the target object 101 includes a mask blank which is coated with resist and on which nothing has been written yet.

A mirror 210 for measuring the position of the XY stage 105 is further arranged on the XY stage 105. In addition, on the XY stage 105, a mark 106 is further arranged so that its surface is located at the same height as the target object 101. As a mark pattern formed on the mark 106, for example, a cross pattern or a rectangular pattern is preferably used.

The control system circuit 160 includes a control calculator 110, a memory 112, a deflection control circuit 130, a logic circuit 131, a digital-to-analog conversion (DAC) amplifier units 132 and 134, a lens control circuit 136, a stage control mechanism 138, a stage position measuring device 139, a deflector control circuit 161, DAC amplifier units 162 and 164, and storage devices 140 and 142 such as magnetic disk drives. The control calculator 110, the memory 112, the deflection control circuit 130, the lens control circuit 136, stage control mechanism 138, the stage position measuring device 139, the deflector control circuit 161, and the storage devices 140 and 142 are connected to each other through a bus (not shown). The DAC amplifier units 132 and 134, the logic circuit 131, the deflector control circuit 161, and the blanking aperture array mechanism 204 are connected to the deflection control circuit 130. The DAC amplifier units 162 and 164 are connected to the deflector control circuit 161.

The deflector 209 is formed by electrodes having four or more poles, and each electrode is controlled by the deflection control circuit 130 through the DAC amplifier 132. The deflector 208 is formed by electrodes having four or more poles, and each electrode is controlled by the deflection control circuit 130 through the DAC amplifier 134.

The deflector 212 is formed by electrodes having two or more poles, and is controlled by the logic circuit 131.

The deflector 214 is formed by electrodes having four or more poles, and each electrode is controlled by the deflection control circuit 161 through the DAC amplifier 162. The deflector 219 is formed by electrodes having four or more poles, and each electrode is controlled by the deflection control circuit 161 through the DAC amplifier 164.

For example, a group of electromagnetic lenses such as the illumination lens 202, the demagnifying lens 205, and the objective lens 207 are controlled by the lens control circuit 136.

The position of the XY stage 105 is controlled by driving motors for each axis (not shown) controlled by the stage control mechanism 138. The stage position measuring device 139 measures the position of the XY stage 105 using the principle of laser interferometry by receiving the reflected light from the mirror 210.

A shot data generation unit 70, a data processing unit 72, a transfer processing unit 74, and a writing control unit 76 are arranged in the control calculator 110. Each “˜ unit”, such as the shot data generation unit 70, the data processing unit 72, the transfer processing unit 74, and the writing control unit 76, has a processing circuit. Examples of such a processing circuit include an electrical circuit, a computer, a processor, a circuit board, a quantum circuit, or a semiconductor device. For each “˜ unit”, a common processing circuit (the same processing circuit) may be used or different processing circuits (separate processing circuits) may be used. Information input to and output from the shot data generation unit 70, the data processing unit 72, the transfer processing unit 74, and the writing control unit 76 and information being calculated are stored in the memory 112 each time.

A deflection control unit 60, a dummy circuit 62, and a current measuring unit 64 are arranged in the deflector control circuit 161. Each of the deflection control unit 60 and the current measuring unit 64 has a processing circuit. Examples of such a processing circuit include an electrical circuit, a computer, a processor, a circuit board, a quantum circuit, or a semiconductor device. In the deflection control unit 60 and the current measuring unit 64, a common processing circuit (the same processing circuit) may be used or different processing circuits (separate processing circuits) may be used. Information input to and output from the deflection control unit 60 and the current measuring unit 64 and information being calculated are stored in a memory (not shown) in the deflector control circuit 161 each time.

The dummy circuit 62 has a circuit configuration similar to that of the circuit in the blanking aperture array mechanism 204. However, since this is merely a dummy circuit, there is no interference with the multiple electron beams 20.

The writing operation of the writing apparatus 100 is controlled by the writing control unit 76. In addition, processing for the transfer of beam irradiation time data of each shot to the deflection control circuit 130 is controlled by the transfer processing unit 74.

In addition, writing data (chip data) is input from outside the writing apparatus 100 and is stored in the storage device 140. The chip data defines information of a plurality of figures forming a chip pattern. Specifically, for each figure, for example, a plurality of vertex coordinates arranged in an order that forms the figure are defined. Alternatively, for example, a figure code, coordinates, size, and the like are defined for each figure.

Here, FIG. 1 describes components necessary for explaining Embodiment 1. The writing apparatus 100 may also include other components that are normally required.

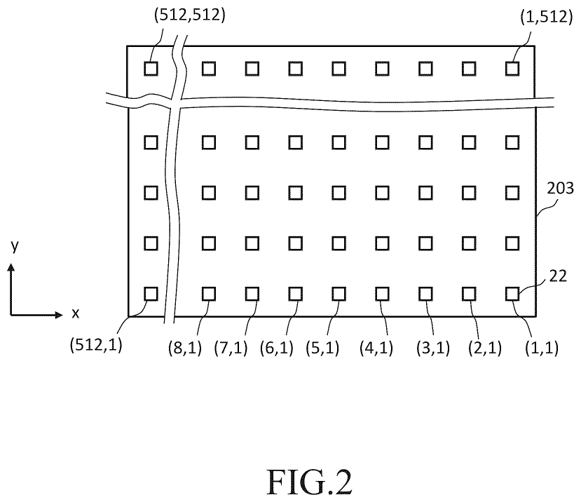

FIG. 2 is a conceptual diagram showing the configuration of a shaping aperture array substrate according to Embodiment 1. In FIG. 2, in the shaping aperture array substrate 203, holes (openings) 22 are formed in a matrix of p rows long (in the x direction) and q columns wide (in the y direction) (p, q≥2) at arrangement pitches. In the example of FIG. 2, a case is shown in which, for example, a 512×512 array of holes 22 are formed in length and width directions (x and y directions). The number of holes 22 is not limited to this. For example, a 64×64 array of holes 22 may be formed. The holes 22 are formed in rectangles having the same size and shape. Alternatively, the holes 22 may be circles having the same diameter. Some of electron beams 200 pass through the plurality of holes 22 to form multiple electron beams 20. In other words, the shaping aperture array substrate 203 forms and emits the multiple electron beams 20. The shaping aperture array substrate 203 is an example of an emission source of the multiple electron beams 20.

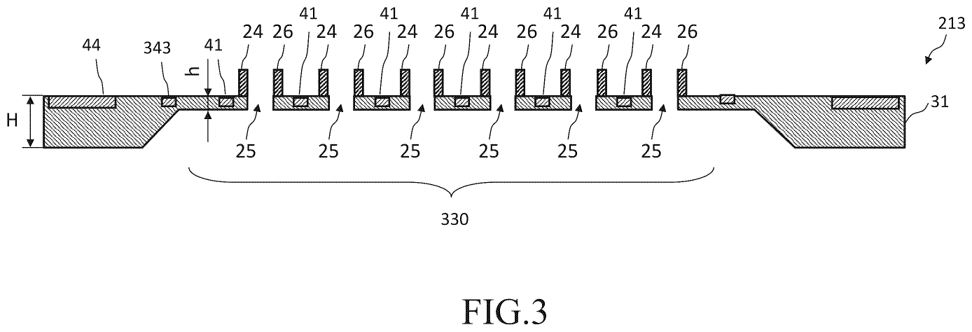

FIG. 3 is a cross-sectional view showing the configuration of a central portion of a blanking aperture array mechanism in Embodiment 1.

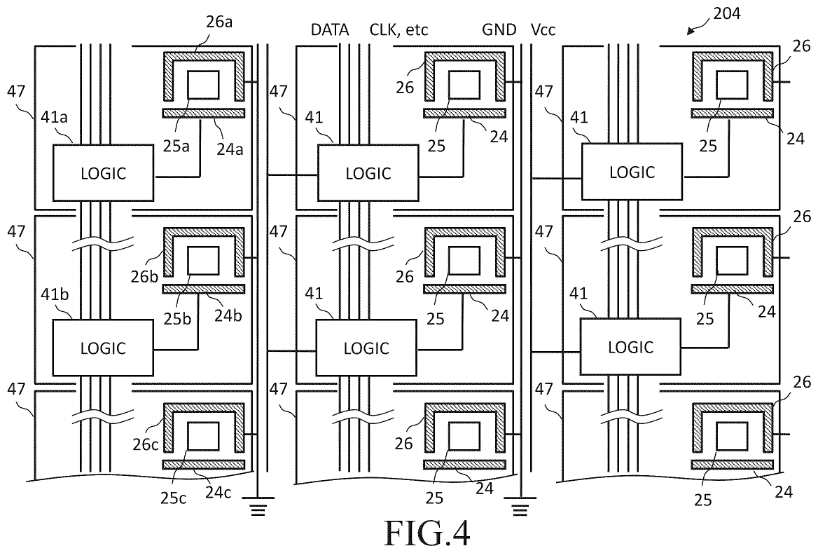

FIG. 4 is a conceptual top view showing a part of the configuration within a membrane region of a blanking aperture array chip in Embodiment 1. In addition, in FIGS. 3 and 4, the positional relationship between a control electrode 24 and a counter electrode 26 and a control circuit 41 is not described in the same manner.

The blanking aperture array chip 213 has a plurality of blankers for individually switching the incident multiple electron beams 20 between a beam ON state and a beam OFF state by beam deflection. Specifically, the blanking aperture array chip 213 is configured as follows. The blanking aperture array chip 213 has a blanking aperture array substrate 31 using a semiconductor substrate formed of silicon or the like, and a thin membrane region 330 is formed in a central portion of the blanking aperture array substrate 31. In a membrane region 330, a passage hole 25 (opening) through which each of the multiple electron beams 20 passes is opened at a position corresponding to each hole 22 of the shaping aperture array substrate 203 shown in FIG. 2. Then, a set of a control electrode 24 and a counter electrode 26 (blanker: blanking deflector) are arranged at positions facing each other with a corresponding passage hole 25 among the plurality of passage holes 25 interposed therebetween. In addition, a control circuit 41 (logic circuit) to apply a deflection voltage to the control electrode 24 for each passage hole 25 is arranged inside the blanking aperture array substrate 31 near each passage hole 25. The counter electrode 26 for each beam is grounded.

In addition, on the blanking aperture array substrate 31 or inside the blanking aperture array substrate 31, a control circuit 44 is arranged on both sides of the membrane region 330 in the x direction, for example.

In addition, as shown in FIG. 4, n-bit (for example, 1-bit) parallel wiring lines for control signals are connected to each control circuit 41. In addition to n-bit parallel wiring lines for beam irradiation time control signal (data), wiring lines for a clock (shift clock) signal, a load signal, a shot signal, and a power supply are connected to each control circuit 41. For these wirings lines and the like, some of the parallel wiring lines may be used. For each beam forming the multiple beams (for each passage hole 25), an individual blanking mechanism 47 is formed by the control electrode 24, the counter electrode 26, and the control circuit 41. In addition, in Embodiment 1, for example, a shift register method is used as a data transfer method. In the shift register method, multiple beams are divided into a plurality of groups for each of the multiple beams, and a plurality of shift registers for multiple beams in the same group are connected in series. Specifically, a plurality of control circuits 41 formed in an array in the membrane region 330 are grouped at a predetermined pitch in the same row or column, for example. The control circuits 41 in the same group are connected in series as shown in FIG. 4. Then, the signal from the pad 343 arranged for each group is transmitted to the control circuit 41 in the group.

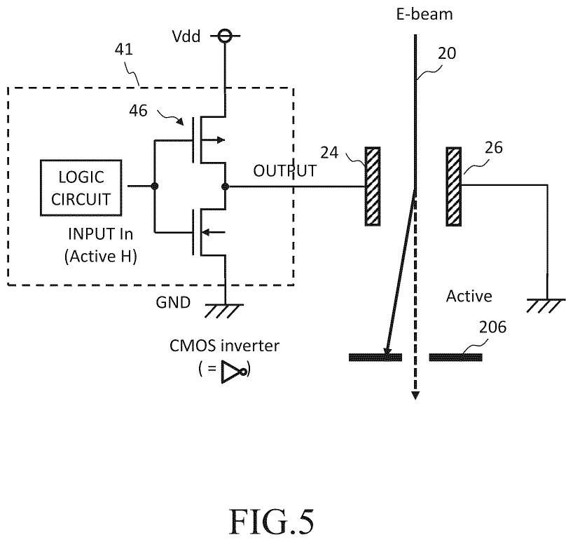

FIG. 5 is a diagram showing an example of an individual blanking mechanism in Embodiment 1. In FIG. 5, in the control circuit 41, an amplifier 46 (an example of a switching circuit) is arranged. As an example of the amplifier 46, a CMOS (Complementary MOS) inverter circuit serving as a switching circuit is arranged. Either an L (low) potential (for example, ground potential) that is lower than the threshold voltage or an H (high) potential (for example, 1.5 V) that is equal to or higher than the threshold voltage is applied to the input (IN) of the CMOS inverter circuit as a control signal. In Embodiment 1, in a state in which the L potential is applied to the input (IN) of the CMOS inverter circuit, the output (OUT) of the CMOS inverter circuit applied to the control circuit 41 has a positive potential (Vdd), and the corresponding beam is deflected by the electric field due to the potential difference from the ground potential of the counter electrode 26 and blocked by the limiting aperture substrate 206. In this manner, the beam is controlled to be turned off. On the other hand, in a state in which the H potential is applied to the input (IN) of the CMOS inverter circuit (active state), the output (OUT) of the CMOS inverter circuit has a ground potential, and there is no potential difference from the ground potential of the counter electrode 26. Therefore, since the corresponding beam is not deflected, the beam passes through the limiting aperture substrate 206. In this manner, the beam is controlled to be turned on. Blanking is controlled by such deflection.

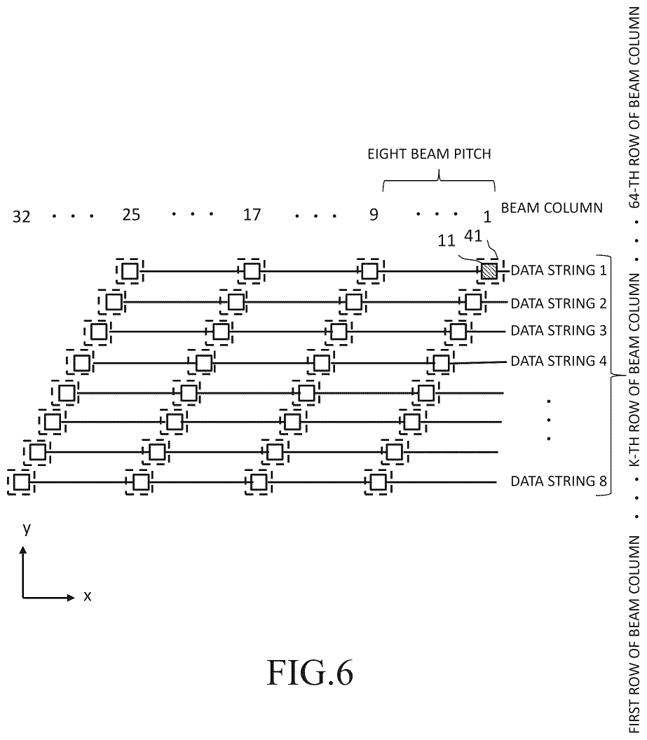

FIG. 6 is a diagram showing an example of a connection configuration of a shift register in Embodiment 1. The control circuit 41 for each beam is formed in an array in the membrane region 330. Then, a plurality of control circuits 41 arranged in an array are separated into left and right halves. For example, for each of the plurality of control circuits 41 (x direction) arranged in the same row on the right half, the columns of control circuits 41 in each row are sequentially sorted and grouped into, for example, eight groups, as shown in FIG. 6. For example, in the case of multiple electron beams 20 in 64 columns×64 rows, the first to 32-th control circuits 41 for beams in each row of the 32 columns in the right half form data string 1 (group) for every eight beam pitches of 1, 9, 17, 25. Similarly, data string 2 (group) is formed for every eight beam pitches of 2, 10, 18, 26. Hereinafter, similarly, data string 3 (group) to data string 8 (group) are formed. Then, the control circuits 41 in each group are connected in series. The same is true for the left half of the plurality of control circuits 41 arranged in an array.

Then, signals for each row output from the deflection control circuit 130 to the blanking aperture array mechanism 204 are divided through a circuit in the mounting board 211 or the control circuit 44 in the blanking aperture array chip 213, and transmitted in parallel to each group. Then, signals of each group are transmitted to the control circuits 41 connected in series in the group. Specifically, a shift register 11 is arranged in each control circuit 41, and the shift registers 11 in the control circuits 41 in the same group are connected in series. In the example of FIG. 6, four shift registers 11 are connected in series for each data string (group). Therefore, when n-bit data is transferred in series, a beam irradiation time control signal (ON/OFF control data) for each beam is transferred (transmitted) to the shift register 11 for each beam in the blanking aperture array mechanism 204 by 4n clock signals. For example, in the case of a configuration capable of emitting 512×512 multiple beams, for example, 32 shift registers 11 are connected in series for each data string (group). Therefore, when n-bit data is transferred in series, a beam irradiation time control signal for each beam is transmitted (transferred) to the shift register 11 for each beam by 32n clock signals.

Then, each individual blanking mechanism 47 controls the beam for the beam irradiation time of the shot according to the beam irradiation time control signal transferred to the shift register 11 for each beam. Here, a divided shot will be described. Alternatively, the beam irradiation time of the shot may be controlled individually for each beam using a counter circuit (not shown).

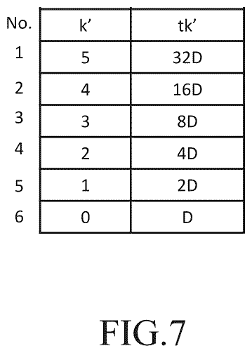

FIG. 7 is a diagram showing an example of divided shots of multiple electron beams in Embodiment 1. In FIG. 7, a maximum beam irradiation time Ttr for one shot is divided into a plurality of sub-shots (divided shots) each having a sub-beam irradiation time. In other words, the maximum beam irradiation time Ttr for one shot of the multiple electron beams 20 is divided into, for example, n sub-shots (divided shots) having different sub-beam irradiation times, which are emitted to the same pixel 36. First, a gradation value Ntr is determined by dividing the maximum beam irradiation time Ttr by a quantization unit Δ (gradation value resolution). For example, when n=6, the maximum beam irradiation time Ttr for one shot is divided into six sub-shots. When the gradation value Ntr is defined as a binary value having n digits, it is preferable to set the quantization unit Δ in advance so that the maximum beam irradiation time Ttr becomes the gradation value Ntr=64. As a result, the maximum beam irradiation time Ttr becomes 64Δ. Then, as shown in FIG. 7, n sub-shots have a beam irradiation time of any one of 2^{k′}Δ, where the number of digits k′=0 to 5. In other words, the n sub-shots have any sub-beam irradiation time of 32Δ (=2⁵Δ), 16Δ (=2⁴Δ), 8Δ (=2³Δ), 4Δ (=2²Δ), 2Δ (=2¹Δ), and Δ (=2⁰Δ). That is, one shot of multiple beams is divided into a sub-shot having a sub-beam irradiation time tk′ of 32Δ, a sub-shot having a sub-beam irradiation time tk′ of 16Δ, a sub-shot having a sub-beam irradiation time tk′ of 8Δ, a sub-shot having a sub-beam irradiation time tk′ of 4Δ, a sub-shot having a sub-beam irradiation time tk′ of 2Δ, and a sub-shot having a sub-beam irradiation time tk′ of Δ. During one shot period, n sub-shots are performed consecutively. The n sub-shots performed during one shot period are each performed with the same beam for each pixel 36.

In addition, the maximum beam irradiation time Ttr corresponds to a beam irradiation time for a pixel with the largest dose among all the pixels 36 in the writing region 30 of the target object 101, in other words, a beam irradiation time when the dose is the largest. In the writing apparatus 100, the constant stage speed is determined by a shot cycle obtained by adding a settling time to the maximum beam irradiation time Ttr.

Therefore, any beam irradiation time t (=NΔ) to be applied to each pixel 36 can be defined by a combination of at least one sub-shot, among the sub-beam irradiation times of a set of sub-shots defined by 32Δ (=2⁵Δ), 16Δ (=2⁴Δ), 8Δ (=2³Δ), 4Δ (=2²Δ), 2Δ (=2¹Δ), and Δ (=2⁰Δ), as long as the beam irradiation time is not zero.

The beam irradiation time data indicating the combination of sub-shots can be defined by 6-bit data in the case of divided shots of n=6. For example, 100000 indicates that 32Δ (k′=5) sub-shots are to be performed. For example, 010000 indicates that 16Δ (k′=4) sub-shots are to be performed. For example, 001000 indicates that 8Δ (k′=3) sub-shots are to be performed. For example, 000100 indicates that 4Δ (k′=2) sub-shots are to be performed. For example, 000010 indicates that 2Δ (k′=1) sub-shots are to be performed. For example, 000001 indicates that 2Δ (k′=0) sub-shots are to be performed. Each bit value indicates one sub-shot. For example, 111111 indicates that 32Δ sub-shots, 16Δ sub-shots, 8Δ sub-shots, 4Δ sub-shots, 2Δ sub-shots, and 1Δ sub-shots are to be performed. In the case of 000000, the beam irradiation time is zero.

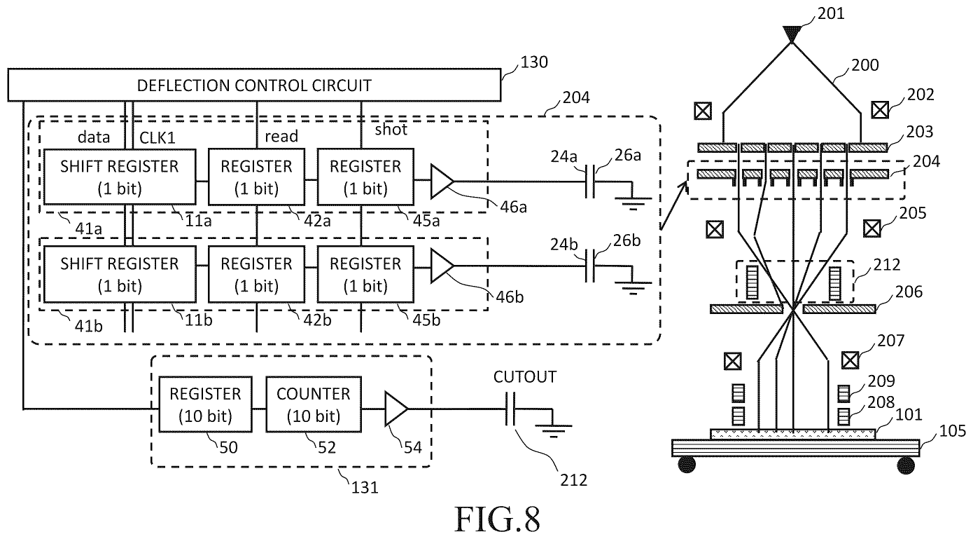

FIG. 8 is a conceptual diagram showing the internal configuration of an individual blanking control circuit and a common blanking control circuit in Embodiment 1. In FIG. 8, a shift register 11, a register 42, a register 45, and an amplifier 46 are arranged in each control circuit 41 for individual blanking control arranged in the blanking aperture array mechanism 204 in the main body of the writing apparatus 100. The individual blanking control for each beam is performed by, for example, a one-bit control signal. That is, for example, a one-bit control signal is input to and output from the shift register 11, the register 42, the register 45, and the amplifier 46. Since the amount of information in the control signal is small, the installation area of the control circuit can be reduced. In other words, even if the control circuit is arranged on the blanking aperture array mechanism 204 having a small installation space, more beams can be arranged with a smaller beam pitch. This can increase the amount of current passing through the blanking plate, that is, improve the writing throughput.

In addition, a register 50, a counter 52, and an amplifier 54 are arranged in the logic circuit 131 for common blanking. Since this does not perform a plurality of different controls at the same time, but requires only one circuit for ON/OFF control, there is no problem with installation space or limitations on the current used by the circuit even when a circuit for high-speed response is arranged. Therefore, the amplifier 54 operates much faster than the amplifier 46 that can be implemented on the blanking aperture array mechanism 204. The amplifier 54 is controlled by, for example, a 10-bit control signal. That is, for example, a 10-bit control signal is input to and output from the register 50 and the counter 52.

In Embodiment 1, blanking control of each beam is performed using both beam ON/OFF control by each control circuit 41 for individual blanking control described above and beam ON/OFF control by the logic circuit 131 for common blanking control that is collective blanking control of all the multiple-beams.

As described above, the shift registers 11 in the control circuits 41 in the same group are connected in series. For example, as shown in the example of FIG. 6, when four shift registers 11 are connected in series for each data string (group) and 1-bit data is transferred in series, the beam irradiation time control signal (ON/OFF control data) for each beam is transferred (transmitted) to the shift register 11 for each beam within the blanking aperture array mechanism 204 by four clock signals.

Then, in response to a read signal input from the deflection control circuit 130, the individual register 42 reads and stores an ON/OFF signal according to the stored data (1 bit) of the k-th sub-shot. In addition, beam irradiation time data (10 bits) of the k-th sub-shot is transmitted from the deflection control circuit 130, and the register 50 for common blanking control stores the beam irradiation time data (10 bits) of the k-th sub-shot.

Then, an individual shot signal of the k-th sub-shot is output from the deflection control circuit 130 to the individual registers 45 of all beams. As a result, the individual register 45 for each beam maintains the data stored in the individual register 42 only for the time during which the individual shot signal is ON, and outputs a beam ON signal or a beam OFF signal to the individual amplifier 46 according to the maintained ON/OFF signal. Instead of the individual shot signal, a load signal for reading and maintaining and a reset signal for resetting the stored information may be output to the individual register 45. The individual amplifier 46 applies a beam ON voltage or a beam OFF voltage to the control electrode 24 according to the input beam ON signal or the beam OFF signal. On the other hand, after the individual shot signal, a common shot signal for the k-th sub-shot is output from the deflection control circuit 130 to the counter 52 for common blanking control, and the counter 52 performs counting for the time indicated by the ON/OFF control signal stored in the register 50 and outputs a beam ON signal to the common amplifier 54 during that time. The common amplifier 54 applies a beam ON voltage to the deflector 212 for the time during which the beam ON signal from the counter 52 is input.

In the common blanking mechanism, for example, as for ON/OFF switching of the individual blanking mechanism 47, switching from OFF to ON is performed after the voltage stabilization time (settling time) S1/S2 of the amplifier 46 passes. After the individual amplifier is turned on, the common amplifier 54 is turned on after the settling time S1 of the individual amplifier 46 at the time of switching from OFF to ON passes. Therefore, it is possible to eliminate beam irradiation with an unstable voltage when the individual amplifier 46 rises. Then, the common amplifier 54 is turned off when the beam irradiation time of the target k-th sub-shot passes. As a result, when both the individual amplifier 46 and the common amplifier 54 are ON, the actual beam becomes ON to be emitted to the target object 101. Therefore, it is preferable to control the ON time of the common amplifier 54 to be the sub-beam irradiation time of the actual beam. On the other hand, when the common amplifier 54 is turned on while the individual amplifier 46 is OFF, it is preferable to turn on the common amplifier 54 after the elapse of the settling time S2 of the individual amplifier 46 at the time of switching from ON to OFF after the individual amplifier 46 is turned off. Therefore, it is possible to eliminate beam irradiation with an unstable voltage when the individual amplifier 46 falls.

In addition, when the beam irradiation time of the shot is controlled individually for each beam using a counter circuit without using a divided shot method, it is not normal to control all beams to OFF at the same time. Therefore, in such a case, the logic circuit 131 and the common blanking deflector 212 may be omitted. In addition, when one shot is divided into a plurality of sub-shots, the same number of beam irradiation time control signals as the number of sub-shots are transferred. On the other hand, the beam irradiation time control signal transferred to the shift register 11 for each beam can be a signal only for selecting ON or OFF of a plurality of sub-shots. Therefore, the number of data bits used for one transfer can be reduced.

Next, a specific example of the operation of the writing mechanism 150 will be described. An electron beam 200 emitted from the electron emission source 201 (emission source) illuminates the entire shaping aperture array substrate 203 almost vertically through the illumination lens 202. A plurality of rectangular holes 22 (openings) are formed in the shaping aperture array substrate 203, and the electron beam 200 illuminates a region including all of the plurality of holes 22. Some of the electron beams 200 emitted to the positions of the plurality of holes 22 pass through the plurality of holes 22 in the shaping aperture array substrate 203 to form, for example, rectangular multiple beams (a plurality of electron beams) 20. Such multiple electron beams 20 pass through corresponding blankers of the blanking aperture array chip 213. Each of the blankers performs blanking control on a beam passing therethrough so that the beam is in an ON state for a set writing time (a combination of at least one sub-beam irradiation time).

The multiple electron beams 20 that have passed through the blanking aperture array chip 213 are reduced by the demagnifying lens 205 and travel toward a central hole formed in the limiting aperture substrate 206. Here, the electron beam deflected by the blanker of the blanking aperture array chip 213 is displaced from the central hole of the limiting aperture substrate 206 and is blocked by the limiting aperture substrate 206. On the other hand, the electron beam that is not deflected by the blanker of the blanking aperture array chip 213 passes through the central hole of the limiting aperture substrate 206 as shown in FIG. 1. Thus, the limiting aperture substrate 206 blocks each beam that is deflected by the blanker of the blanking aperture array chip 213 so as to be in a beam OFF state. Then, by the beam that has passed through the limiting aperture substrate 206 and is formed from the beam ON state to the beam OFF state, each beam of one shot is formed. The multiple electron beams 20 that have passed through the limiting aperture substrate 206 are focused by the objective lens 207 to become a pattern image having a desired reduction ratio, and all of the multiple electron beams 20 that have passed through the limiting aperture substrate 206 are collectively deflected in the same direction by the deflector 208 and the deflector 209 and emitted to each irradiation position on the target object 101 of each beam. In addition, for example, when the XY stage 105 is continuously moving, tracking control is performed by the deflector 208 so that the irradiation position of the beam follows the movement of the XY stage 105. The multiple electron beams 20 emitted at one time are ideally arranged at a pitch obtained by multiplying the arrangement pitch of the plurality of holes 22 of the shaping aperture array substrate 203 by the desired reduction ratio described above.

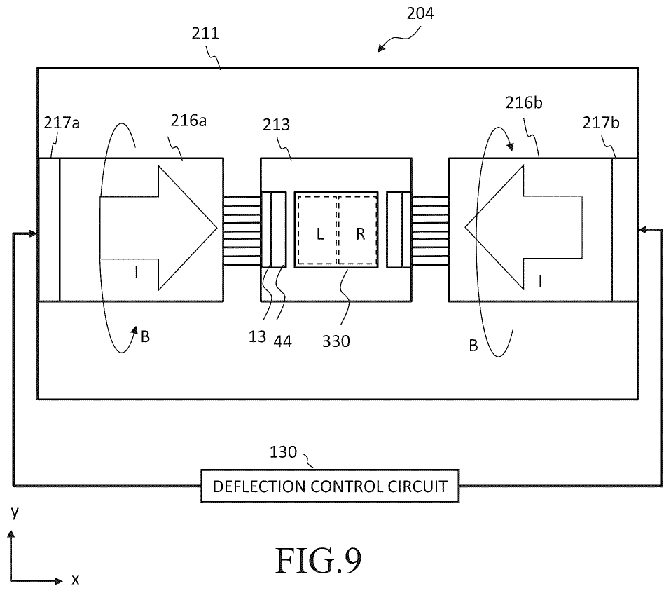

FIG. 9 is a top view of an example of a blanking aperture array mechanism in Embodiment 1.

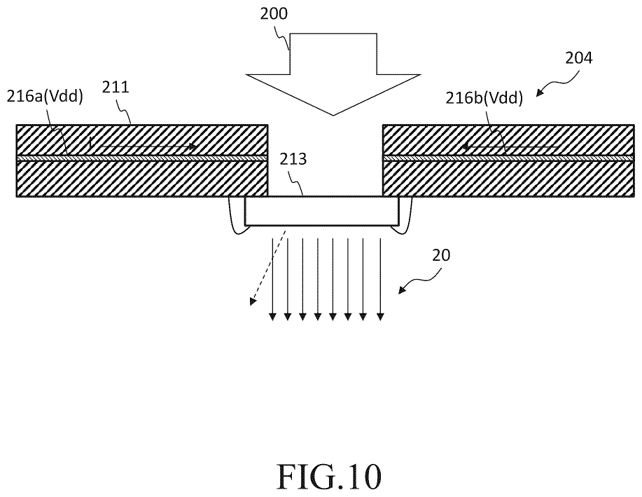

FIG. 10 is a cross-sectional view of an example of the blanking aperture array mechanism in Embodiment 1.

In FIGS. 9 and 10, the mounting board 211 supports the blanking aperture array chip 213. Specifically, as shown in FIG. 9, the blanking aperture array chip 213 is arranged so as to block an opening of the mounting board 211 formed in a central portion thereof. As shown in FIG. 10, the blanking aperture array chip 213 is arranged on the back surface side of the mounting board 211.

As described above, a plurality of control circuits 41 arranged in an array in the membrane region 330 in the blanking aperture array chip 213 are controlled by dividing these into left and right halves in the x direction. Then, in the left half, a plurality of control circuits 41 arranged in the same row further form a plurality of groups. Similarly, in the right half, a plurality of control circuits 41 arranged in the same row further form a plurality of groups. In the blanking aperture array chip 213, the control circuit 44 for controlling a plurality of groups in the left half and an interface circuit 13 are arranged near the outer periphery outside the membrane region 330. Similarly, in the blanking aperture array chip 213, the control circuit 44 for controlling a plurality of groups in the right half and the interface circuit 13 are arranged near the outer periphery outside the membrane region 330.

Then, a power supply plane 216 and other signal circuits are formed within the mounting board 211. The power supply plane 216 supplies power to the blanking aperture array chip 213. The power supply plane 216 serves as a power supply for the transistors of each logic circuit with a voltage Vdd, for example. Hereinafter, a specific description will be given.

On the mounting board 211, on the left side of the blanking aperture array chip 213 in the x direction, a layer of a power supply plane (surface power supply) 216a for supplying power to a plurality of groups in the left half of the blanking aperture array chip 213, a circuit layer of signal lines (not shown), and an interface circuit 217a are formed. The power supply plane 216a is connected to the control circuit 44 on the left side through the interface circuit 13 on the left side. Then, the power supply plane 216a functions as a power supply for the control circuit 44. In other words, the power supply plane 216a makes a current flow to the control circuit 44. The circuit layer of signal lines (not shown) is connected to the control circuit 44 on the left side through the interface circuit 13 on the left side. Then, the circuit layer of signal lines outputs a control signal to the control circuit 44. Power and signals are supplied from the deflection control circuit 130 to the layer of the power supply plane 216a and the circuit layer of signal lines through the interface circuit 217a.

Similarly, on the mounting board 211, on the right of the blanking aperture array chip 213 in the x direction, a layer of a power supply plane (surface power supply) 216b for supplying power to a plurality of groups in the right half of the blanking aperture array chip 213, a circuit layer of signal lines (not shown), and an interface circuit 217b are formed. The power supply plane 216a is connected to the control circuit 44 on the right side through the interface circuit 13 on the right side. Then, the power supply plane 216b functions as a power supply for the control circuit 44. In other words, the power supply plane 216b makes a current flow to the control circuit 44. The circuit layer of signal lines (not shown) is connected to the control circuit 44 on the right side through the interface circuit 13 on the right side. Then, the circuit layer of signal lines outputs a control signal to the control circuit 44. Power and signals are supplied from the deflection control circuit 130 to the layer of the power supply plane 216b and the circuit layer of signal lines through the interface circuit 217b.

As described above, the shift register 11 is driven to transmit data to each control circuit 41 in the blanking aperture array chip 213. Power is consumed to drive such a shift register 11. Then, during beam ON/OFF, a current flows through the amplifier 46 in each control circuit 41. To perform these controls at high speed, a large amount of current may flow at one time. For this reason, the power supply plane 216 is formed in the mounting board 211. Here, a magnetic field B is generated by the circuit current (operating current) flowing through the mounting board 211 (power supply plane 216). This causes positional deviations of the multiple electron beams 20.

Therefore, in Embodiment 1, the positional deviations of the multiple electron beams 20 due to the magnetic field B caused by the circuit current (operating current) flowing through the power supply plane 216 are corrected.

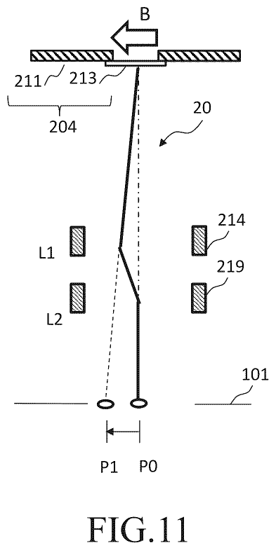

FIG. 11 is a diagram for explaining the positional deviations of multiple electron beams and a correction method in Embodiment 1. Due to the magnetic field B generated by the current flowing through the power supply plane 216 formed on the mounting board 211 of the blanking aperture array mechanism 204, the trajectory of the multiple electron beams 20 passing through the blanking aperture array chip 213 is changed. If this state continues, a positional deviation from a designed position P0 to a position P1 on the surface of the target object 101 occurs. Since the magnetic field B acts on all of the multiple electron beams 20, it can be considered that positional deviations of all of the multiple electron beams 20 occur in the same direction by the same amount.

In Embodiment 1, the multiple electron beams 20 that have passed through the blanking aperture array mechanism 204 are deflected by one or more stages of deflectors 215 (deflectors 214 and 219). Specifically, the deflector control circuit 161 controls one or more stages of deflectors 215 (deflectors 214 and 219) so as to correct the positional deviations of the multiple electron beams 20 due to the current flowing through the power supply plane 216. In other words, the trajectory of the multiple electron beams 20 is returned to the trajectory in the absence of the magnetic field B by beam deflection. In the example of FIG. 11, the multiple electron beams 20, whose trajectory has deviated, is bent by the first-stage deflector 214 to its original trajectory (a trajectory when no magnetic field acts), and then bent by the second-stage deflector 219 so as to match the original trajectory. When only one stage of deflector (for example, the deflector 214) is used, the multiple electron beams 20 are deflected so as to be located at the designed position P0 on the target object surface.

In a state in which a positional deviation actually occurs, the mark 106 may be scanned with, for example, the central beam of the multiple electron beams 20, and the position P1 may be measured from the obtained image.

Here, the amount of deflection LA (deflection vector) for correcting the amount of positional deviation is defined as P0-P1. In addition, the amount of deflection LΔ can be defined by the following Equation (1) using an x-direction deflection voltage L₁ₓ and a y-direction deflection voltage L_{1y} of the deflector 214, an x-direction deflection voltage L₂ₓ and a y-direction deflection voltage L_{2y} of the deflector 219, correction coefficients a_{L}, b_{L}, c_{L}, and d_{L}, and correction coefficients a_{R}, b_{R}, c_{R}, and d_{R}.

$$Δ L = {a}_{L} {L}_{1 x} + {b}_{L} {L}_{1 y} + {c}_{L} {L}_{2 x} + {d}_{L} {L}_{2 y} + {a}_{R} {L}_{1 x} + {b}_{R} {L}_{1 y} + {c}_{R} {L}_{2 x} + {d}_{R} {L}_{2 y} \qquad ( 1 )$$

In addition, a_{L}L₁ₓ+b_{L}L_{1y}+c_{L}L₂ₓ+d_{L}L_{2y} indicates the amount of deflection for correcting the amount of positional deviation due to the magnetic field generated by the current flowing through the power supply plane 216a on the left side. a_{R}L₁ₓ+b_{R}L_{1y}+c_{R}L₂ₓ+d_{R}L_{2y} indicates the amount of deflection for correcting the amount of positional deviation due to the magnetic field generated by the current flowing through the power supply plane 216b on the right side. Using a plurality of pieces of irradiation pattern data, the operating current of each piece of irradiation pattern data, the deflection voltage of each of the deflectors 214 and 219, and the amount of deflection for correcting the amount of positional deviation are measured. Then, each of these is substituted into Equation (1) to create a plurality of equations. Then, the plurality of equations are set up simultaneously, and the correction coefficients a_{L}, b_{L}, c_{L}, and d_{L} and the correction coefficients a_{R}, b_{R}, c_{R}, and d_{R} that best satisfy each equation are found in advance. The obtained correction coefficient information is set in the deflector control circuit 161.

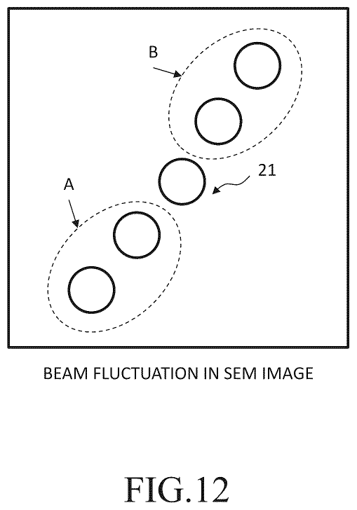

FIG. 12 is a diagram for explaining an example of the positional deviations of multiple electron beams in Embodiment 1. FIG. 12 shows the irradiation position of a central beam 21, among the multiple electron beams 20, on the target object surface. Compared to the irradiation position on the original trajectory (a trajectory when no magnetic field acts), for example, due to the influence of a magnetic field generated on the left side of the mounting board 211, the irradiation position of the central beam 21 deviates to the lower left side (part A). The amount of deviation depends on the value of the current (operating current) flowing through the power supply plane 216a on the left side. Similarly, for example, due to the influence of a magnetic field generated on the right side of the mounting board 211, the irradiation position of the central beam 21 deviates to the upper right side (part B). The amount of deviation depends on the value of the current (operating current) flowing through the power supply plane 216b on the right side.

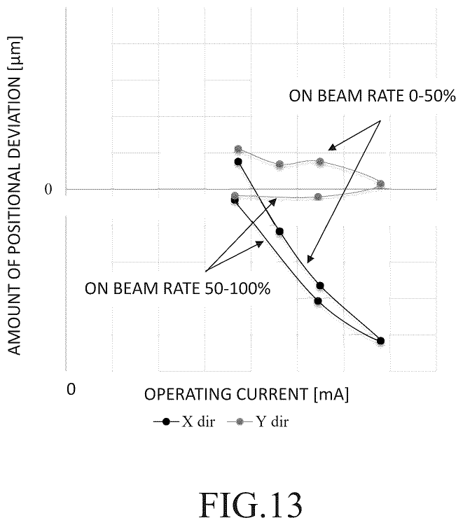

FIG. 13 is a diagram showing an example of the relationship between the operating current and the amount of positional deviation in Embodiment 1. FIG. 13, the vertical axis indicates the amount of positional deviation. The horizontal axis indicates the operating current. FIG. 13 shows the amount of positional deviation in the x direction and the amount of positional deviation in the y direction. As shown in FIG. 13, it can be seen that the amount of positional deviation due to the magnetic field B generated by the operating current flowing through the power supply plane 216 of the mounting board 211 depends on the operating current. In the example of FIG. 13, as the operating current increases, the amount of positional deviation Δx increases, for example, to the negative side. In the power supply plane 216a shown in FIG. 9, most of a current I flows from left to right. In other words, most of the current I flows in the x direction. There is no flow in the y direction. Alternatively, even if there is any flow in the y direction, the amount is only small. When the operating current of the power supply plane 216a on the left side is changed, as shown in FIG. 13, in the x direction in which the operating current of the power supply plane 216a on the left side flows, it can be seen that the amount of positional deviation Δx of the beam changes according to the magnitude of the change in the operating current. Conversely, in the y direction in which almost no operating current flows, it can be seen that the change in the amount of positional deviation Δy is small. In addition, a power supply plane serving as a power supply for the transistors of each logic circuit having a voltage Vdd, a power supply plane serving as a power supply for the I/O circuits of signal lines, and the like are formed on the mounting board 211. In the I/O circuit, a difference from the standby current is small, so that the amount of fluctuation is small. On the other hand, in each logic circuit having a voltage Vdd, the difference from the standby current is large. For this reason, the amount of beam positional deviation is larger in each logic circuit having a voltage Vdd than in the I/O circuit. Therefore, it can be seen that the influence of the power supply plane serving as a power supply for the I/O circuits of the signal lines is sufficiently small compared to the influence of the power supply plane 216 serving as a power supply for the transistors of each logic circuit having a voltage Vdd.

Therefore, if the value of the operating current is known for each shot (for each sub-shot in the case of the divided shot method), the amount of deflection (deflection vector) for correcting the positional deviation can be determined. Here, the operating current changes s depending on the ON beam rate. The ON beam rate indicates the rate of beams in which sub-shots having the same sub-beam irradiation time are ON among the multiple electron beams 20. In the example of FIG. 13, the relationship between the operating current and the amount of positional deviation when the ON beam rate is 0 to 50% and the relationship between the operating current and the amount of positional deviation when the ON beam rate is 50 to 100% are shown as examples.

The example of FIG. 13 shows the results of measuring the amount of positional deviation when a current is made to flow through the mounting board 211 using a plurality of pieces of irradiation pattern data with different ON beam rates. Each case when the ON beam rate is, for example, 0%, 25%, 50%, 75%, and 100% is measured.

In addition, even if sub-shots have the same ON beam rate, the operating current may differ depending on the relationship with the preceding and following sub-shots. For example, when the beam irradiation time data of a certain beam is 000111, the 32Δ sub-shot is OFF, the 16Δ sub-shot is OFF, and the 8Δ sub-shot is OFF. On the other hand, the 4Δ sub-shot is ON, the 2Δ sub-shot is ON, and the 1Δ sub-shot is ON. Therefore, the value of the current that flows only once between the 8Δ sub-shot and the 4Δ sub-shot changes. In contrast, for example, when the beam irradiation time data of a certain beam is 101010, the 32Δ sub-shot is ON, the 16Δ sub-shot is OFF, the 8Δ sub-shot is ON, the 4Δ sub-shot is OFF, the 2Δ sub-shot is ON, and the 1Δ sub-shot is OFF. Therefore, ON/OFF is repeated for each sub-shot, and the value of the current that flows changes each time. In such a case, the operating current may increase even in the case of the sub-shots having the same ON beam ratio for which ON/OFF is repeated.

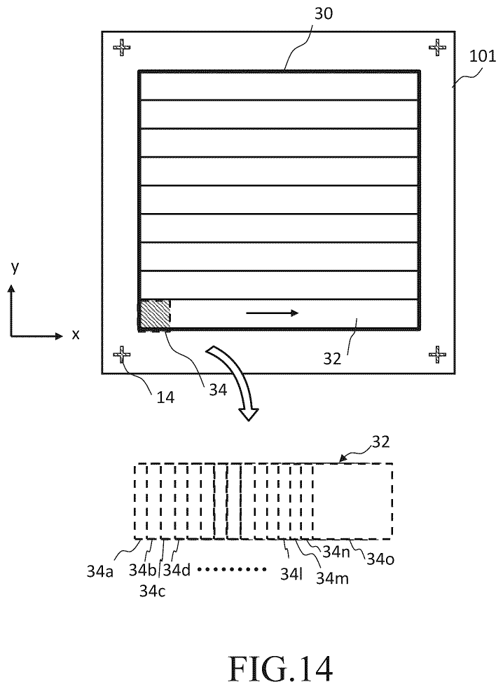

FIG. 14 is a conceptual diagram for explaining an example of the writing operation in Embodiment 1. As shown in FIG. 14, the position of the writing region 30 (bold line) of the target object 101 is defined with the position of an alignment mark 14 as a reference.

The writing region 30 (bold line) is virtually divided into a plurality of rectangular striped regions 32 with a predetermined width in the y direction, for example. The example of FIG. 14 shows a case where the writing region 30 of the target object 101 is divided into a plurality of striped regions 32, for example, in the y direction, with the substantially the same width as the designed size of the irradiation region 34 (writing field) that can be irradiated with one-time multiple electron beams 20.

First, the XY stage 105 is moved to make an adjustment so that the irradiation region 34 of the multiple electron beams 20 is located at the left end of the first striped region 32 or further to the left, and writing in the first striped region 32 is performed. When writing the first striped region 32, the XY stage 105 is moved, for example, in the −x direction, so that the writing proceeds relatively in the x direction. The XY stage 105 is continuously moved, for example, at a constant speed. After the writing in the first striped region 32 ends, the stage position is moved in the −y direction by the width of the striped region 32.

Then, an adjustment is made so that the irradiation region 34 of the multiple electron beams 20 is located at the left end of the second striped region 32 or further to the left, and the XY stage 105 is moved, for example, in the −x direction so that the writing proceeds relatively in the x direction. In this manner, the writing in the second striped region 32 is performed.

In addition, although the case where the writing in each striped region 32 proceeds in the same direction is shown in the example of FIG. 14, the invention is not limited thereto. For example, for the striped region 32 to be written next to the striped region 32 where writing has proceeded in the x direction, the writing may be performed in the −x direction by moving the XY stage 105, for example, in the x direction. By performing writing while alternately changing the direction in this manner, the stage movement time can be shortened, and the writing time can be shortened. In one shot, by the multiple electron beams 20 formed by passing through each hole 22 of the shaping aperture array substrate 203, a plurality of shot patterns, up to the same number as each hole 22, are formed at a time.

In addition, although the case where the stage movement for writing in each striped region is performed once at a time is shown in the example of FIG. 14, the invention is not limited thereto. It is also preferable to perform multi-writing so that the stage moves N times (N is an integer of 2 or more) on the same position. In this case, for example, it is preferable to perform multi-writing while shifting in the y direction by a shift amount of 1/N of the width of the striped region.

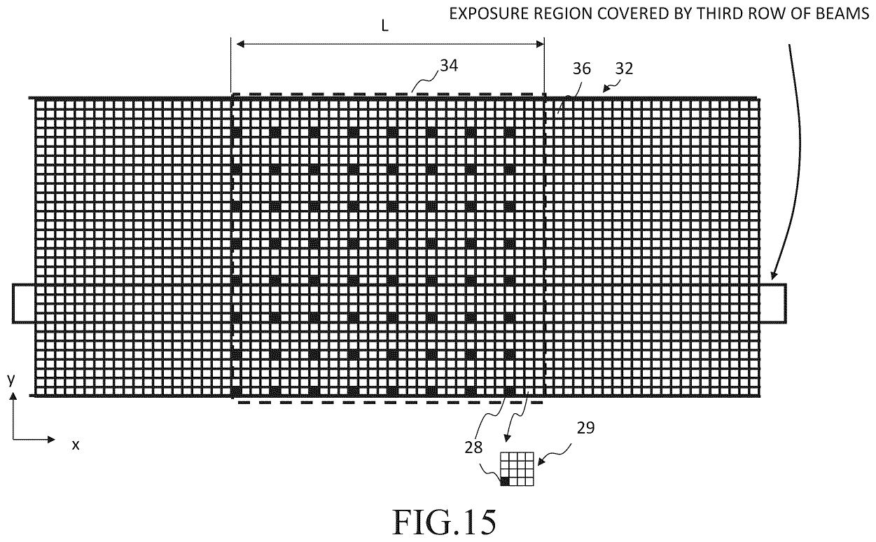

FIG. 15 is a diagram showing an example of a region irradiated with multiple beams and a writing target pixel in Embodiment 1. In FIG. 15, the striped region 32 is divided into a plurality of mesh regions with the beam size of the multiple electron beams 20, for example. Each of such mesh regions is a writing target pixel 36 (unit irradiation region, irradiation position, or writing position). The size of the writing target pixel 36 is not limited to the beam size, and may be any size regardless of the beam size. For example, the size of the writing target pixel 36 may be 1/n (n is an integer of 1 or more) of the beam size. In the example of FIG. 15, a case is shown in which the writing region of the target object 101 is divided into a plurality of striped regions 32, for example, in the y direction, with the substantially the same width as the size of the irradiation region 34 (writing field) that can be irradiated with one-time multiple electron beams 20. The designed size of the rectangular irradiation region 34 in the x direction can be defined as the number of beams in the x direction x the pitch between beams in the x direction. The size of the rectangular irradiation region 34 in the y direction can be defined as the number of beams in the y direction x the pitch between beams in the y direction. In the example of FIG. 15, for example, a 512×512 array of multiple beams is abbreviated to an 8×8 array of multiple beams. Then, in the irradiation region 34, a plurality of pixels 28 (beam writing positions) that can be irradiated with one shot of the multiple electron beams 20 are shown. The pitch between the pixels 28 adjacent to each other is the pitch between the multiple beams. A rectangular region surrounded with the size of the beam pitch in the x and y directions is one sub-irradiation region 29 (pitch cell). In the example of FIG. 15, a case is shown in which each sub-irradiation region 29 is formed by, for example, 4×4 pixels.

In a shot data generation step, first, the shot data generation unit 70 generates shot data for each pixel 36. Specifically, the shot data generation unit 70 operates as follows. First, the shot data generation unit 70 reads writing data from the storage device 140, and calculates a pattern area density ρ′ within the pixel 36 for each pixel 36. Such processing is performed for each striped region 32, for example.

Then, the shot data generation unit 70 first virtually divides the writing region (here, for example, the striped region 32) into a plurality of proximity mesh regions (mesh regions for proximity effect correction calculation) in a mesh form with a predetermined size. The size of the proximity mesh region is preferably set to about 1/10 of the range of influence of the proximity effect, for example, about 1 μm. The shot data generation unit 70 reads out writing data from the storage device 140, and calculates, for each proximity mesh region, a pattern area density ρ″ of the pattern to be arranged in that proximity mesh region.

Then, the shot data generation unit 70 calculates a proximity effect-corrected exposure intensity Dp(x) for correcting the proximity effect for each proximity mesh region. The unknown proximity effect-corrected exposure intensity Dp(x) can be defined by a threshold model for proximity effect correction that is similar to that in the conventional method and uses a back scattering coefficient η, an exposure intensity threshold Dth of the threshold model, a pattern area density ρ″, and a distribution function g(x). The proximity effect-corrected exposure intensity Dp(x) is defined as a relative value normalized with the base exposure density of the beam Dbase being 1.

Then, the shot data generation unit 70 calculates, for each pixel 36, an incident exposure intensity D(x) (dose) for irradiating the pixel 36. The incident exposure intensity D(x) may be calculated, for example, as a value obtained by multiplying the base exposure density of the beam Dbase by the proximity effect-corrected exposure intensity Dp and the pattern area density ρ′. The base exposure density of the beam Dbase can be defined as Dth/(1/2+η), for example. As described above, it is possible to obtain the incident exposure intensity D(x) for each pixel 36 with the proximity effect corrected, based on the layout of a plurality of figures defined in the writing data.

Then, the shot data generation unit 70 calculates a beam irradiation time for each pixel 36. The beam irradiation time for each pixel 36 can be calculated by dividing the incident exposure intensity D(x) of the pixel by the current density J.

In a data processing step, the data processing unit 72 rearranges the obtained beam irradiation time data for each pixel 36 in the order of shots and stores the beam irradiation time data in the storage device 142. The transfer processing unit 74 transfers irradiation pattern data, which is a compilation of bit data corresponding to the order of sub-shots among the pieces of beam irradiation time data of pixels that are targets of the shot, to the deflection control circuit 130.

In a writing step, the deflection control circuit 130 outputs the irradiation pattern data in the order of sub-shots to the blanking aperture array mechanism 204, and controls the blanking aperture array mechanism 204. In addition, the deflection control circuit 130 generates 10-bit data for each sub-shot of the divided shot, outputs the data to the logic circuit 131 in the order of sub-shots, and controls the logic circuit 131. In addition, the deflection control circuit 130 outputs to the DAC amplifier units 132 and 134 deflection data for deflecting the multiple electron beams 20 to the irradiation positions for each shot.

In addition, the deflection control circuit 130 outputs irradiation pattern data to be output to the blanking aperture array mechanism 204 to the deflector control circuit 161 in parallel. In the deflector control circuit 161, the dummy circuit 62 receives the irradiation pattern data and is controlled by the irradiation pattern data. In other words, the dummy circuit 62 receives the irradiation pattern data and performs an operation similar to that of the circuit in the blanking aperture array mechanism 204.

Then, the current measuring unit 64 (an example of a current prediction unit (current acquisition unit)) acquires the current flowing through the power supply plane 216. Specifically, the current measuring unit 64 measures the current flowing through a power supply plane (not shown) of the dummy circuit 62 as a result of the dummy circuit 62 being controlled by the irradiation pattern data. In this manner, the current flowing through the power supply plane 216 of the mounting board 211 is predicted.

Then, under the control of the writing control unit 76, the writing mechanism 150 writes a pattern on the target object 101 on the XY stage 105 using the multiple electron beams 20 while moving the XY stage 105. In multi-beam writing, beam irradiation time data of a region to be subjected to writing processing later is generated while performing writing processing. For example, shot data for the (k+2)-th striped region 32 is generated while performing writing in the k-th striped region 32. While repeating this operation, writing in all of the striped regions 32 is performed.

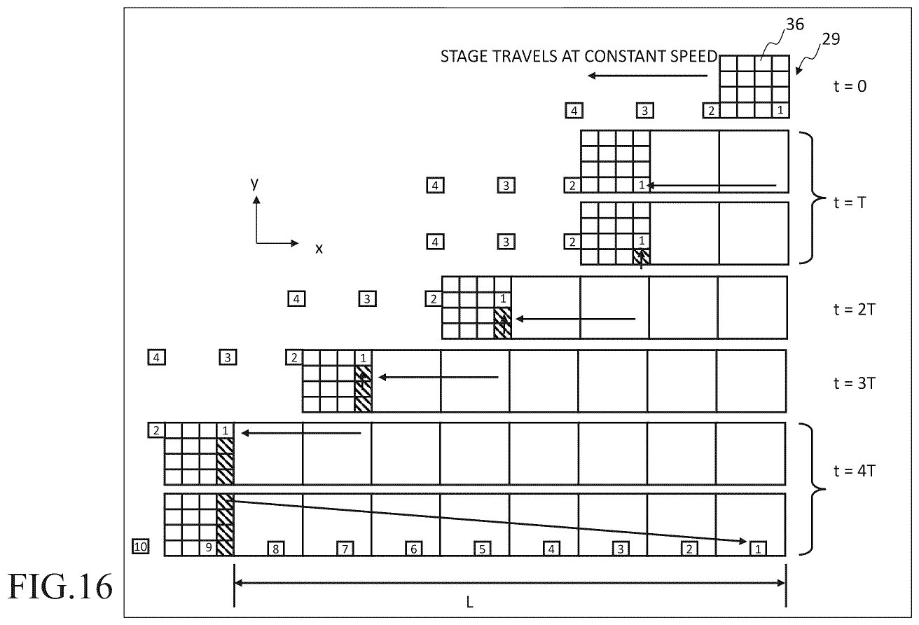

FIG. 16 is a diagram for explaining an example of a multi-beam writing operation in Embodiment 1. In the example of FIG. 16, a case is shown in which each sub-irradiation region 29 including one beam irradiation position of the multiple electron beams 20 and surrounded with the pitch between beams is written with four different beams. In addition, the example of FIG. 16 shows a writing operation in which the XY stage 105 moves continuously at a speed for movement by a distance of, for example, eight beam pitches while writing a ¼ region (1/the number of beams used for irradiation) in each sub-irradiation region 29. In the example of FIG. 16, a case is shown in which each sub-irradiation region 29 is formed by, for example, 4×4 pixels.

In the writing operation shown in the example of FIG. 16, for example, four different pixels 36 within the same sub-irradiation region 29 are written (exposed) by performing four shots of the multiple electron beams 20 with a shot cycle T while shifting the irradiation position (pixel 36) sequentially by the deflector 209 during the movement of the XY stage 105 by a distance of eight beam pitches in the x direction.

Each shot is a combination of at least one sub-shot as described above.

The irradiation region 34 is caused to follow the movement of the XY stage 105 by collectively deflecting all of the multiple electron beams 20 with the deflector 208, so that the relative position of the irradiation region 34 with respect to the target object 101 does not shift due to the movement of the XY stage 105, while writing (exposing) the four pixels 36. In other words, tracking control is carried out. When one tracking cycle ends, the tracking is reset to return to the previous tracking start position. In addition, since the writing of the first pixel column from the left of each sub-irradiation region 29 has been completed, in the next tracking cycle after tracking reset, the deflector 209 first performs deflection to match (shift) the writing position of the beam, which is different from the first pixel column, so as to write, for example, the second pixel column from the left that has not yet been written in each sub-irradiation region 29. By repeating this operation while writing the striped region 32, the position of the irradiation region 34 (34a to 34o) of the multiple electron beams 20 is sequentially moved as shown in the lower diagram of FIG. 14 to perform writing.

In each sub-shot, the blanking aperture array mechanism 204 performs control to switch the multiple electron beams individually between a beam ON state and a beam OFF state based on the irradiation pattern data. At this time, the current flowing through the power supply plane 216 is measured (predicted) by the current measuring unit 64.

The deflection control unit 60 calculates the amount of deflection ΔL for correcting the positional deviation from the measured current value. The amount of deflection ΔL may be calculated as a value (vector with the direction inverted) obtained by inverting the sign of the obtained amount of positional deviation (positional deviation vector) with reference to the relationship in FIG. 13.

Then, the deflection control unit 60 calculates the deflection voltages of the deflectors 214 and 219 according to the amount of deflection ΔL. Specifically, the amount of deflection ΔL is input to Equation (1) using the set correction coefficients a_{L}, b_{L}, c_{L}, and d_{L} and correction coefficients a_{R}, b_{R}, c_{R}, and d_{R} and the deflection voltages of the deflectors 214 and 219 that satisfy Equation (1) are calculated.

The deflection control unit 60 controls, for each sub-shot, one or more stages of deflectors 215 (deflectors 214 and 219) so as to correct the positional deviations of the multiple electron beams 20 due to the current flowing through the power supply plane 216. Then, for each sub-shot, one or more stages of deflectors 215 (deflectors 214 and 219) deflect the multiple electron beams 20 so as to correct the positional deviations of the multiple electron beams 20 due to the current flowing through the power supply plane 216.

Alternatively, the operating current in each piece of irradiation pattern data, the deflection angle ratio between the deflectors 214 and 219, and the amount of deflection ΔL (deflection vector) for correcting the amount of positional deviation are measured by using a plurality of pieces of irradiation pattern data. Then, it is also preferable to obtain in advance a relationship between the amount of deflection ΔL (deflection vector) and the deflection angle ratio between the deflectors 214 and 219 and set the relationship between the amount of deflection ΔL and the deflection angle ratio in the deflector control circuit 161. For example, a correction coefficient is calculated by fitting the relationship between the amount of deflection ΔL and the deflection angle ratio with a polynomial, and is set in the deflector control circuit 161. Then, in this case, the deflection control unit 60 may control the deflectors 214 and 219 with a deflection angle ratio according to the amount of deflection ΔL.

Then, the remaining electron optical system 151, excluding the one or more stages of deflectors 215, irradiates the target object 101 with the multiple electron beams 20 whose positional deviations have been corrected.

Here, there may be a case where a multipole magnetic field occurs as the magnetic field B described above. This may cause astigmatism in the multiple electron beams 20. Here, there may be a case where various multipole magnetic fields are included as the magnetic field B. The major influences are expected to be from the deflection magnetic field (dipole field) and/or the magnetic field (quadrupole field) of the stigmator. However, the arrangement relationship between the location where the quadrupole magnetic field is generated and the location where a normal stigmator is installed is different from that of the optical system. Therefore, it is also preferable to superimpose a quadrupole field on the deflection field of one or more stages of deflectors 215 (deflectors 214 and 219). In this manner, it is possible to correct distortions such as astigmatism of the multiple electron beams 20. In this case, it is preferable that one or more stages of deflectors 215 (deflectors 214 and 219) have a quadrupole or more. For example, it is preferable that one or more stages of deflectors 215 (deflectors 214 and 219) have eight-pole electrodes.

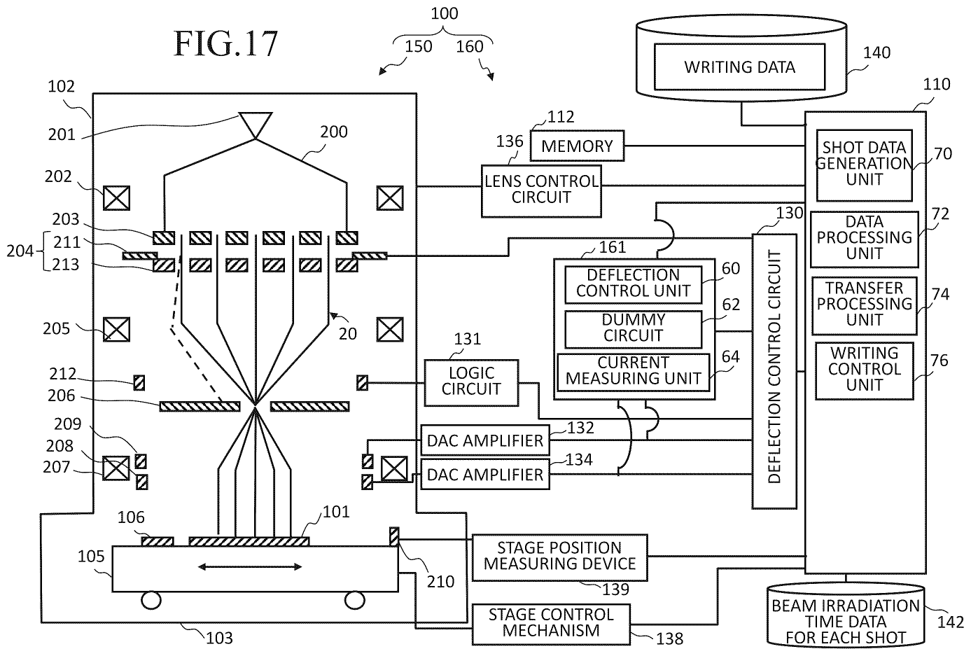

FIG. 17 is a diagram showing an example of the configuration of a writing apparatus according to a modification example of Embodiment 1. In FIG. 17, deflectors 208 and 209 function as one or more stages of deflectors 215 (deflectors 214 and 219). Therefore, the configuration of the writing apparatus according to the modification example of Embodiment 1 is the same as that in FIG. 1 except that the one or more stages of deflectors 215 (deflectors 214 and 219) and the DAC amplifier units 162 and 164 are removed.

Specifically, for example, the deflector 209 functions as the deflector 214. Similarly, the deflector 208 functions as the deflector 219. In other words, one or more stages of deflectors 215 (deflectors 214 and 219) serve as the deflectors 208 and 209, which are objective deflectors for deflecting the multiple electron beams 20 to desired positions on the target object 101.

Therefore, the deflection control unit 60 outputs a signal of a deflection voltage to be applied to the deflector 214 to the DAC amplifier unit 132 so that the deflection voltage to be applied to the deflector 214 is added to the deflection voltage to be applied to the deflector 209 for each sub-shot. Similarly, the deflection control unit 60 outputs a signal of a deflection voltage to be applied to the deflector 219 to the DAC amplifier unit 134 so that the deflection voltage to be applied to the deflector 219 is added to the deflection voltage to be applied to the deflector 208 for each sub-shot.

Then, for each sub-shot, the deflectors 208 and 209 deflect the multiple electron beams 20 to their original irradiation positions, and deflect the multiple electron beams 20 so as to correct the positional deviations of the multiple electron beams 20 due to the current flowing through the power supply plane 216.

In this manner, the positional deviations of the multiple electron beams 20 due to the current flowing through the power supply plane 216 may be corrected by using the existing deflectors 208 and 209.

As described above, according to Embodiment 1, it is possible to correct the positional deviations of the multiple electron beams 20 due to the magnetic field B generated by the circuit current (operating current) flowing through the mounting board 211 on which the blanking aperture array chip 213 through which the multiple electron beams 20 pass is arranged.

### Embodiment 2

In Embodiment 1, the case has been described in which the circuit current (operating current) flowing through the mounting board 211 is predicted by the deflector control circuit 161 using a dummy circuit, but the invention is not limited thereto. In Embodiment 2, a configuration for measuring a circuit current (operating current) flowing through the mounting board 211 in the deflection control circuit 130 that controls the blanking aperture array mechanism 204 will be described. The contents other than those specifically described below are the same as those in Embodiment 1.

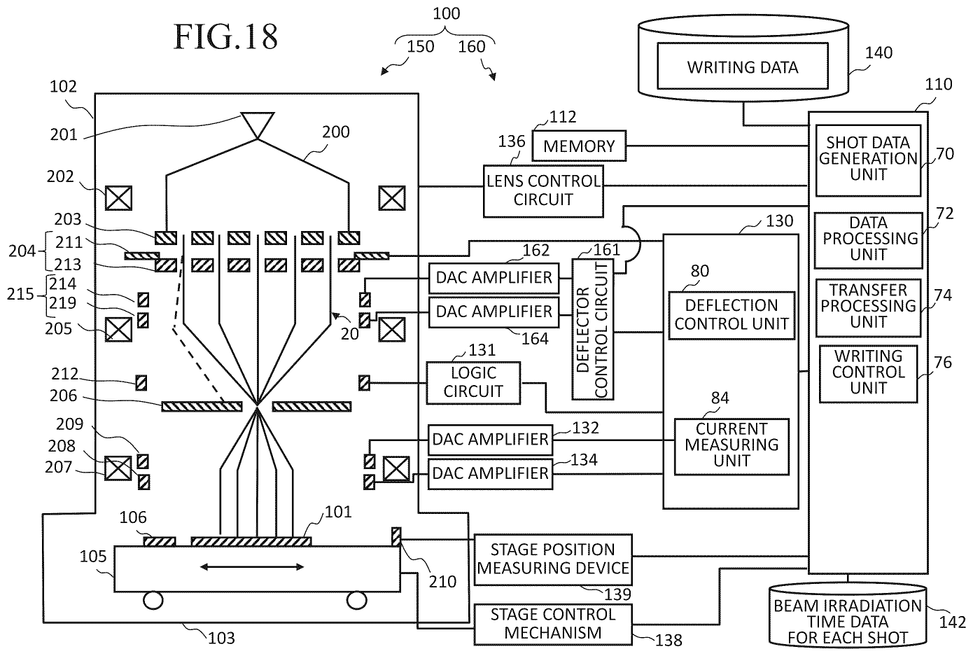

FIG. 18 is a diagram showing an example of the configuration of a writing apparatus according to Embodiment 2. FIG. 18 is the same as FIG. 1 except that a deflection control unit 80 having the function of the deflection control circuit 130 in Embodiment 1 and a current measuring unit 84 are arranged in the deflection control circuit 130, the deflector control circuit 161 has the function of the deflection control unit 60 in Embodiment 1, and the dummy circuit 62 and the current measuring unit 64 are removed.

The deflection control unit 80 and the current measuring unit 84 each have a processing circuit. Examples of such a processing circuit include an electrical circuit, a computer, a processor, a circuit board, a quantum circuit, or a semiconductor device. For the deflection control unit 80 and the current measuring unit 84, a common processing circuit (the same processing circuit) may be used or different processing circuits (separate processing circuits) may be used. Information input to and output from the deflection control unit 80 and the current measuring unit 84 and information being calculated are stored in a memory (not shown) in the deflection control circuit 130 each time.

The contents of each step up to the transfer of the irradiation pattern data to the deflection control circuit 130 in the order of sub-shots are the same as those in Embodiment 1.

In a writing step, the deflection control circuit 130 outputs the irradiation pattern data in the order of sub-shots to the blanking aperture array mechanism 204, and controls the blanking aperture array mechanism 204. In addition, the deflection control circuit 130 generates 10-bit data for each sub-shot of the divided shot, outputs the data to the logic circuit 131 in the order of sub-shots, and controls the logic circuit 131. In addition, the deflection control circuit 130 outputs to the DAC amplifier units 132 and 134 deflection data for deflecting the multiple electron beams 20 to the irradiation positions for each shot.

Then, the current measuring unit 84 (an example of a current prediction unit (current acquisition unit)) acquires the current flowing through the power supply plane 216. Specifically, the current measuring unit 84 measures the current flowing from the deflection control circuit 130 to the power supply plane 216.

In addition, the deflection control circuit 130 outputs the measured value of the current flowing through the power supply plane 216 to the deflector control circuit 161.

Then, under the control of the writing control unit 76, the writing mechanism 150 writes a pattern on the target object 101 on the XY stage 105 using the multiple electron beams 20 while moving the XY stage 105.

At this time, the deflector control circuit 161 calculates the amount of deflection ΔL for correcting the positional deviation from the measured current value. The amount of deflection ΔL may be calculated by referring to the relationship in FIG. 13.

Then, the deflector control circuit 161 calculates the deflection voltages of the deflectors 214 and 219 according to the amount of deflection ΔL, as in Embodiment 1.

Then, the deflector control circuit 161 controls, for each sub-shot, one or more stages of deflectors 215 (deflectors 214 and 219) so as to correct the positional deviations of the multiple electron beams 20 due to the current flowing through the power supply plane 216. Then, for each sub-shot, one or more stages of deflectors 215 (deflectors 214 and 219) deflect the multiple electron beams 20 so as to correct the positional deviations of the multiple electron beams 20 due to the current flowing through the power supply plane 216. Alternatively, the deflector control circuit 161 may control the deflectors 214 and 219 with a deflection angle ratio according to the amount of deflection ΔL, as in Embodiment 1.

In addition, as in the modification example of Embodiment 1, it is also preferable that the deflectors 208 and 209, which are objective deflectors for deflecting the multiple electron beams 20 to desired positions on the target object 101, function as one or more stages of deflectors 215 (deflectors 214 and 219). In other words, one or more stages of deflectors 208 and 209 have both a function of deflecting the multiple electron beams 20 so as to correct the positional deviations of the multiple electron beams 20 due to the current flowing through the power supply plane 216 and a function of an objective deflector that deflects the multiple electron beams 20 to desired positions on the target object 101.

In addition, as in Embodiment 1, it is also preferable to superimpose a quadrupole field on the deflection field of one or more stages of deflectors 215 (deflectors 214 and 219).

As described above, according to Embodiment 2, the circuit current (operating current) flowing through the mounting board 211 on which the blanking aperture array chip 213 through which the multiple electron beams 20 pass is arranged is measured within the deflection control circuit 130, and the measurement result is transmitted to the deflector control circuit 161. In this manner, it is possible to correct the positional deviations of the multiple electron beams 20 due to the magnetic field B generated by the circuit current (operating current).

### Embodiment 3

In Embodiment 3, a configuration for measuring (predicting) a circuit current (operating current) flowing through the mounting board 211 in the control calculator 110 will be described. The contents other than those specifically described below are the same as those in Embodiment 1.

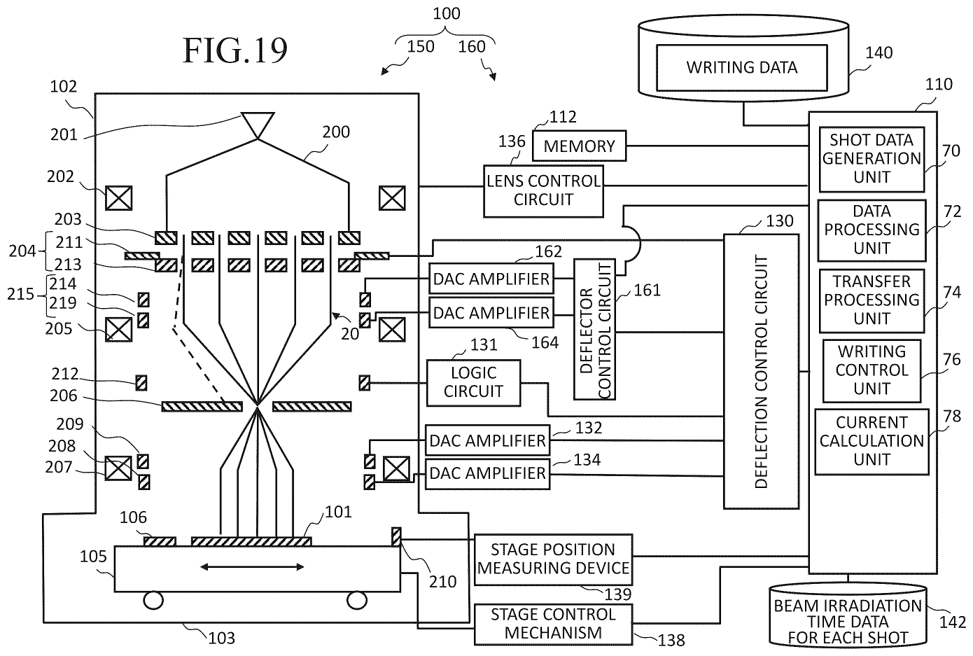

FIG. 19 is a diagram showing an example of the configuration of a writing apparatus according to Embodiment 3. FIG. 19 is the same as FIG. 1 except that a current calculation unit 78 is added in the control calculator 110, the deflector control circuit 161 has the function of the deflection control unit 60 in Embodiment 1, and the dummy circuit 62 and the current measuring unit 64 are removed.

Each “˜ unit”, such as the shot data generation unit 70, the data processing unit 72, the transfer processing unit 74, the writing control unit 76, and the current calculation unit 78 has a processing circuit. Examples of such a processing circuit include an electrical circuit, a computer, a processor, a circuit board, a quantum circuit, or a semiconductor device. For each “˜ unit”, a common processing circuit (the same processing circuit) may be used or different processing circuits (separate processing circuits) may be used. Information input to and output from the shot data generation unit 70, the data processing unit 72, the transfer processing unit 74, the writing control unit 76, and the current calculation unit 78 and information being calculated are stored in the memory 112 each time.

The contents of each step up to the transfer of the irradiation pattern data to the deflection control circuit 130 in the order of sub-shots are the same as those in Embodiment 1.

The current calculation unit 78 (an example of a current prediction unit (current acquisition unit)) acquires the current flowing through the power supply plane 216. Specifically, the current calculation unit 78 calculates (predicts) the current flowing from the deflection control circuit 130 to the power supply plane 216, for each sub-shot, based on the irradiation pattern data. Specifically, a current actually flowing from the deflection control circuit 130 to the power supply plane 216 is measured in advance using a plurality of pieces of irradiation pattern data, and relationship data between the irradiation pattern data and the current is measured. Then, the relationship between the irradiation pattern data and the current is fitted with a polynomial, and the obtained coefficients are stored in the storage device 142 or the like. The current calculation unit 78 calculates a current value according to the irradiation pattern data by using the polynomial of such coefficients. The calculated (predicted) current value is output to the deflector control circuit 161.

In a writing step, the deflection control circuit 130 outputs the irradiation pattern data in the order of sub-shots to the blanking aperture array mechanism 204, and controls the blanking aperture array mechanism 204. In addition, the deflection control circuit 130 generates 10-bit data for each sub-shot of the divided shot, outputs the data to the logic circuit 131 in the order of sub-shots, and controls the logic circuit 131. In addition, the deflection control circuit 130 outputs to the DAC amplifier units 132 and 134 deflection data for deflecting the multiple electron beams 20 to the irradiation positions for each shot.

Then, under the control of the writing control unit 76, the writing mechanism 150 writes a pattern on the target object 101 on the XY stage 105 using the multiple electron beams 20 while moving the XY stage 105.

At this time, the deflector control circuit 161 calculates the amount of deflection ΔL for correcting the positional deviation from the calculated (predicted) current value. The amount of deflection ΔL may be calculated by referring to the relationship in FIG. 13.

Then, the deflector control circuit 161 calculates the deflection voltages of the deflectors 214 and 219 according to the amount of deflection ΔL, as in Embodiment 1.

Then, the deflector control circuit 161 controls, for each sub-shot, one or more stages of deflectors 215 (deflectors 214 and 219) so as to correct the positional deviations of the multiple electron beams 20 due to the current flowing through the power supply plane 216. Then, for each sub-shot, one or more stages of deflectors 215 (deflectors 214 and 219) deflect the multiple electron beams 20 so as to correct the positional deviations of the multiple electron beams 20 due to the current flowing through the power supply plane 216. Alternatively, the deflector control circuit 161 may control the deflectors 214 and 219 with a deflection angle ratio according to the amount of deflection ΔL, as in Embodiment 1.

In addition, as in the modification example of Embodiment 1, it is also preferable that the deflectors 208 and 209, which are objective deflectors for deflecting the multiple electron beams 20 to desired positions on the target object 101, function as one or more stages of deflectors 215 (deflectors 214 and 219). In other words, one or more stages of deflectors 208 and 209 have both a function of deflecting the multiple electron beams 20 so as to correct the positional deviations of the multiple electron beams 20 due to the current flowing through the power supply plane 216 and a function of an objective deflector that deflects the multiple electron beams 20 to desired positions on the target object 101.

In addition, as in Embodiment 1, it is also preferable to superimpose a quadrupole field on the deflection field of one or more stages of deflectors 215 (deflectors 214 and 219).

As described above, according to Embodiment 3, the circuit current (operating current) flowing through the mounting board 211 is calculated (predicted) by the control calculator 110 that generates the irradiation pattern data, and the calculation result is transmitted to the deflector control circuit 161. In this manner, it is possible to correct the positional deviations of the multiple electron beams 20 due to the magnetic field B generated by the circuit current (operating current).

### Embodiment 4

In each of the above embodiments, the case has been described in which the amount of correction (the amount of deflection) for correcting the positional deviations of the multiple electron beams 20 due to the magnetic field B generated by the circuit current (operating current) is calculated in real time in the actual writing step, but the invention is not limited thereto. In Embodiment 4, a configuration will be described in which the amount of correction is calculated in advance offline and then the writing process is performed. The contents other than those specifically described below are the same as those in Embodiment 1.

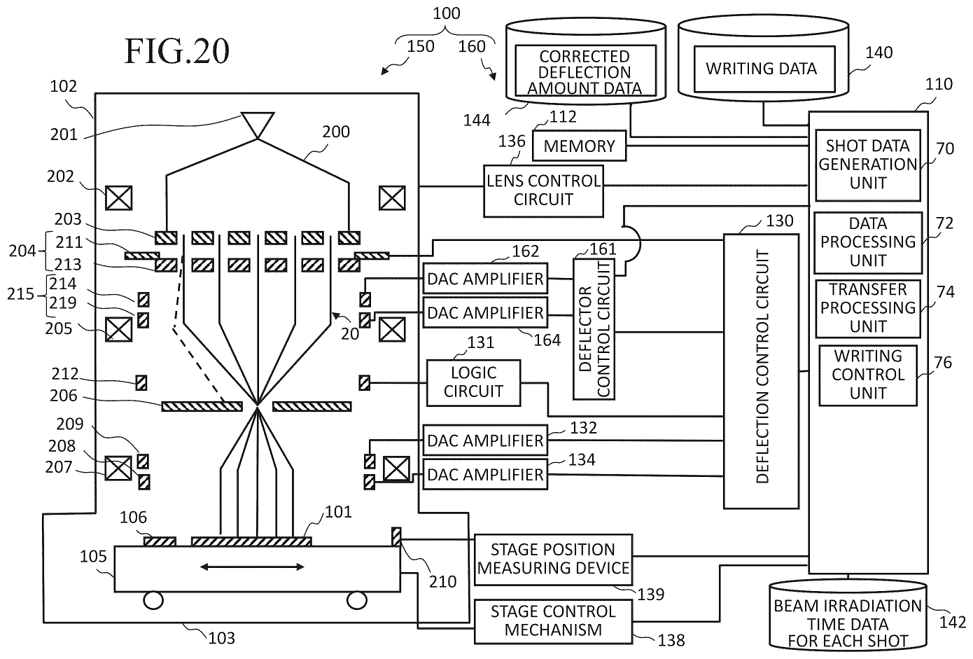

FIG. 20 is a diagram showing an example of the configuration of a writing apparatus according to Embodiment 4. FIG. 20 is the same as FIG. 1 except that a storage device 144 such as a magnetic disk drive is added, the deflector control circuit 161 has the function of the deflection control unit 60 in Embodiment 1, and the dummy circuit 62 and the current measuring unit 64 are removed.

In Embodiment 4, the amount of correction for correcting the positional deviations of the multiple electron beams 20 due to the current flowing through the power supply plane 216 is calculated offline in the order of shots (here, in the order of sub-shots). Then, correction amount information that defines the amount of correction is created. The created correction amount information is input from, for example, the outside of the writing apparatus 100 and stored in the storage device 144. Such correction amount information may be created in the writing apparatus 100.

The amount of correction is preferably calculated as, for example, the amount of deflection ΔL for correcting the positional deviation. Specifically, beam irradiation time data for each pixel 36 is generated in advance offline, and irradiation pattern data in the order of sub-shots is generated. Then, for example, using such irradiation pattern data, the current flowing from the deflection control circuit 130 to the power supply plane 216 is calculated (predicted) for each sub-shot. The calculation method is the same as in Embodiment 3. Then, the amount of deflection ΔL for correcting the positional deviation is calculated from the calculated (predicted) current value.

Alternatively, the amount of deflection ΔL for correcting the positional deviation may be calculated as the value of a current flowing from the deflection control circuit 130 to the power supply plane 216. Alternatively, it is also preferable to calculate the amount of deflection ΔL for correcting the positional deviation as deflection voltage data of one or more stages of deflectors 215 (deflectors 214 and 219).

Then, under the control of the writing control unit 76, the writing mechanism 150 writes a pattern on the target object 101 on the XY stage 105 using the multiple electron beams 20 while moving the XY stage 105.

At this time, the deflector control circuit 161 calculates the deflection voltages of the deflectors 214 and 219 according to the amount of deflection ΔL, as in Embodiment 1, using the amount of deflection ΔL (the amount of correction) defined in the correction amount information with reference to the correction amount information stored in the storage device 144.

Then, the deflector control circuit 161 controls, for each sub-shot, one or more stages of deflectors 215 (deflectors 214 and 219) so as to correct the positional deviations of the multiple electron beams 20 due to the current flowing through the power supply plane 216. In other words, the deflector control circuit 161 controls, for each shot (here, for each sub-shot), one or more stages of deflectors 215 (deflectors 214 and 219) using the amount of correction for the sub-shot so as to correct the positional deviations of the multiple electron beams 20 due to the current flowing through the power supply plane 216 with reference to the correction amount information. Then, for each sub-shot, one or more stages of deflectors 215 (deflectors 214 and 219) deflect the multiple electron beams 20 so as to correct positional deviations of the multiple electron beams 20 due to the current flowing through the power supply plane 216. Alternatively, the deflector control circuit 161 may control the deflectors 214 and 219 with a deflection angle ratio according to the amount of deflection ΔL, as in Embodiment 1.

In addition, as in the modification example of Embodiment 1, it is also preferable that the deflectors 208 and 209, which are objective deflectors for deflecting the multiple electron beams 20 to desired positions on the target object 101, function as one or more stages of deflectors 215 (deflectors 214 and 219). In other words, one or more stages of deflectors 208 and 209 have both a function of deflecting the multiple electron beams 20 so as to correct the positional deviations of the multiple electron beams 20 due to the current flowing through the power supply plane 216 and a function of an objective deflector that deflects the multiple electron beams 20 to desired positions on the target object 101.

In addition, as in Embodiment 1, it is also preferable to superimpose a quadrupole field on the deflection field of one or more stages of deflectors 215 (deflectors 214 and 219).

As described above, according to Embodiment 4, the amount of correction is calculated in advance offline, and the calculation result is transmitted to the deflector control circuit 161. Therefore, it is possible to correct the positional deviations of the multiple electron beams 20 due to the magnetic field B generated by the circuit current (operating current).

### Embodiment 5

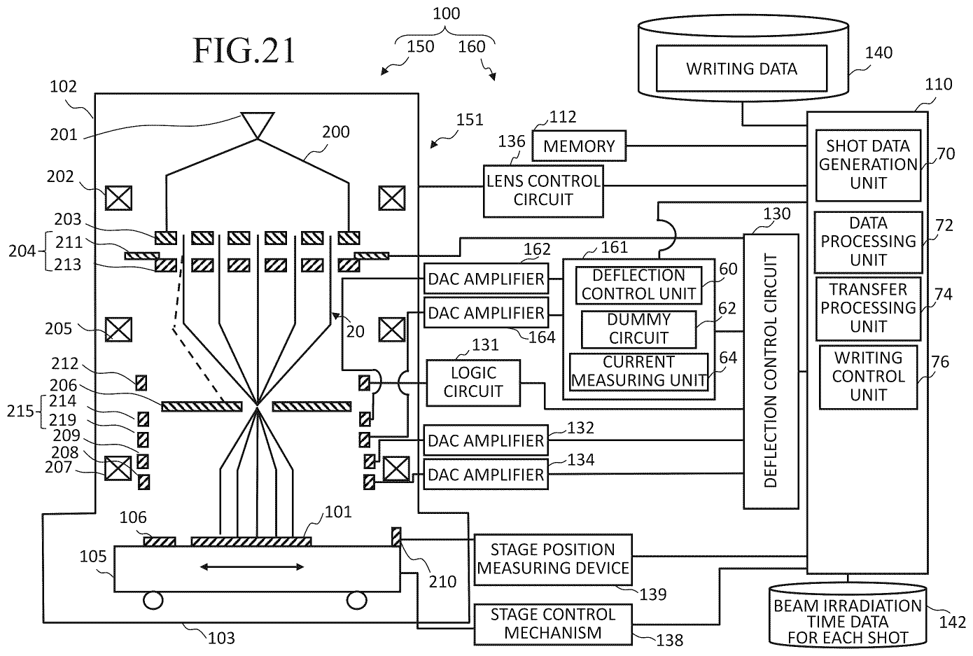

FIG. 21 is a conceptual diagram showing the configuration of a writing apparatus according to Embodiment 5. The example of FIG. 21 is the same as FIG. 1 except that one or more stages of deflectors 215 (deflectors 214 and 219) are arranged between the limiting aperture substrate 206 and the target object 101. Thus, one or more stages of deflectors 208 and 209 may not have a function of deflecting the multiple electron beams 20 so as to correct the positional deviations of the multiple electron beams 20 due to the current flowing through the power supply plane 216, and one or more stages of deflectors 215 (deflectors 214 and 219) may be arranged, for example, near the deflectors 208 and 209.

Similarly, in the above Embodiments 2 to 4 as well, one or more stages of deflectors 215 (deflectors 214 and 219) may be arranged between the limiting aperture substrate 206 and the target object 101.

Up to now, the embodiments have been described with reference to specific examples. However, the invention is not limited to these specific examples.

In addition, the description of parts that are not directly required for the description of the present invention, such as the apparatus configuration or the control method, is omitted. However, the required apparatus configuration, control method, and the like can be appropriately selected and used. For example, although the description of the control unit configuration for controlling the writing apparatus 100 is omitted, it is needless to say that the required control unit configuration can be appropriately selected and used.

In addition, all multi-charged particle beam writing apparatuses that include the elements of the invention and that can be appropriately redesigned by those skilled in the art are included in the scope of the invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-charged particle beam writing apparatus, comprising:
a blanking aperture array mechanism having
a blanking aperture array chip having a plurality of blankers for individually switching incident multi-charged particle beams between a beam ON state and a beam OFF state by beam deflection and
a mounting board configured to support the blanking aperture array chip, a power supply plane for supplying power to the blanking aperture array chip being formed in the mounting board;
a limiting aperture substrate configured to block a beam in the beam OFF state among the multi-charged particle beams having passed through the blanking aperture array mechanism;
a current acquisition circuit configured to acquire a current flowing through the power supply plane;
one or more stages of deflectors configured to deflect the multi-charged particle beams having passed through the blanking aperture array mechanism;
a deflector control circuit configured to control the one or more stages of deflectors so as to correct positional deviations of the multi-charged particle beams due to the current flowing through the power supply plane;
a stage, a target object being placed on the stage; and
an electron optical system configured to irradiate the target object with the multi-charged particle beams with positional deviations corrected.

2. The apparatus according to claim 1, further comprising:
a deflection control circuit configured to control the blanking aperture array mechanism,
wherein the deflection control circuit has a current measuring circuit serving as the current acquisition circuit, configured to be arranged in the deflection control circuit, and to measure a current flowing from the deflection control circuit to the power supply plane.

3. The apparatus according to claim 1, further comprising:
a deflection control circuit configured to control the blanking aperture array mechanism,
wherein the deflection control circuit outputs irradiation pattern data to the blanking aperture array mechanism,
the blanking aperture array mechanism controls to individually switch the multi-charged particle beams between the beam ON state and the beam OFF state based on the irradiation pattern data, and
the deflector control circuit has
a dummy circuit configured to have a same circuit configuration as a circuit in the blanking aperture array mechanism, receive the irradiation pattern data, and be controlled by the irradiation pattern data and
a current prediction circuit serving as the current acquisition circuit, configured to predict the current flowing through the power supply plane by measuring a current flowing through a power supply plane of the dummy circuit due to the dummy circuit being controlled by the irradiation pattern data.

4. The apparatus according to claim 1, further comprising:
a storage device configured to store writing data for writing the target object; and
a control calculator configured to perform data conversion of the writing data into irradiation pattern data,
wherein the control calculator serving as the current acquisition circuit, further calculates the current flowing through the power supply plane based on the irradiation pattern data.

5. A multi-charged particle beam writing apparatus, comprising:
a blanking aperture array mechanism having
a blanking aperture array chip having a plurality of blankers for individually switching incident multi-charged particle beams between a beam ON state and a beam OFF state by beam deflection and
a mounting board configured to support the blanking aperture array chip, a power supply plane for supplying power to the blanking aperture array chip being formed in the mounting board;
a limiting aperture substrate configured to block a beam in the beam OFF state among the multi-charged particle beams having passed through the blanking aperture array mechanism;
one or more stages of deflectors configured to deflect the multi-charged particle beams having passed through the blanking aperture array mechanism;
a storage device configured to store, in order of shots, correction amount information defining an amount of correction for correcting positional deviations of the multi-charged particle beams due to a current flowing through the power supply plane, the amount of correction being calculated in advance offline;
a deflector control circuit configured to control, for each shot, the one or more stages of deflectors using the amount of correction for a shot so as to correct the positional deviations of the multi-charged particle beams due to the current flowing through the power supply plane with reference to the correction amount information;
a stage, a target object being placed on the stage; and
an electron optical system configured to irradiate the target object with the multi-charged particle beams with positional deviations corrected.

6. The apparatus according to claim 1,
wherein the one or more stages of deflectors are arranged between the blanking aperture array mechanism and the limiting aperture substrate.

7. The apparatus according to claim 1,
wherein the one or more stages of deflectors also serve as an objective deflector configured to deflect the multi-charged particle beams to desired positions on the target object.

8. The apparatus according to claim 5,
wherein the one or more stages of deflectors are arranged between the blanking aperture array mechanism and the limiting aperture substrate.

9. The apparatus according to claim 5,
wherein the one or more stages of deflectors also serve as an objective deflector configured to deflect the multi-charged particle beams to desired positions on the target object.

10. The apparatus according to claim 1, further comprising:
an objective deflector configured to deflect the multi-charged particle beams to desired positions on the target object, the objective deflector being arranged between the limiting aperture substrate and the target object,
wherein the one or more stages of deflectors are arranged between the limiting aperture substrate and the target object separately from the objective deflector.
